(19) United States
(12) Patent Application Publication
(10) Pub. No.: US 2025/0167113 A1
(43) Pub. Date: May 22, 2025

(54) INTEGRATED CIRCUIT DEVICE

(71) Applicant: Samsung Electronics Co., Ltd., Suwon-si (KR)

(72) Inventors: Jeewoong KIM, Suwon-si (KR); Jinkyu KIM, Suwon-si (KR); Yunsuk NAM, Suwon-si (KR); Yoonbeom PARK, Suwon-si (KR); Keunhwi CHO, Suwon-si (KR)

(73) Assignee: Samsung Electronics Co., Ltd., Suwon-si (KR)

(21) Appl. No.: 18/754,295

(22) Filed: Jun. 26, 2024

(30) Foreign Application Priority Data
Nov. 16, 2023 (KR) 10-2023-0159478

(51) Int. Cl. H01L 23/528; H01L 21/8238; H01L 27/092; H01L 29/06; H01L 29/423; H01L 29/66; H01L 29/775; H01L 29/786

(52) U.S. Cl. CPC H01L 23/5283; H01L 23/528; H01L 23/5286; H10D 30/014; H10D 30/43; H10D 30/6735; H10D 30/6757; H10D 62/121; H10D 64/017; H10D 84/0186; H10D 84/038; H10D 84/85

(57) ABSTRACT

Provided is an integrated circuit device including first and second power lines each overlapping a first cell region, an inter-cell separation region, and a second cell region on a substrate in a vertical direction to the substrate, a first power tap cell penetrating through the substrate and receiving a first voltage from the first power line, a second power tap cell penetrating through the substrate and receiving, from the second power line, a second voltage different from the first voltage, and a dummy gate insulating bridge including first and second dummy gate insulating lines, which are apart from each other with the first and second power tap cells therebetween, and defining a vacuum space, and connected to the first and second dummy gate insulating lines.

### CROSS-REFERENCE TO RELATED APPLICATION

This application is based on and claims priority under 35 U. S. C. § 119 to Korean Patent Application No. 10-2023-0159478, filed on Nov. 16, 2023 in the Korean Intellectual Property Office, the disclosure of which is incorporated by reference herein in its entirety.

### BACKGROUND

The inventive concepts relate to integrated circuit devices, and particularly, to integrated circuit devices including a power line.

As the miniaturization, multifunctionalization, and high-performance of electronic products are required, integrated circuit devices with high capacity and high integration have been required. Accordingly, it is beneficial to efficiently design insulating structures and insulating structures for separation to achieve high integration while securing the functions and operation speed required in integrated circuit devices.

### SUMMARY

The inventive concepts provide integrated circuit devices to reduce a dielectric constant between power tap cells.

The inventive concepts provide integrated circuit devices having a structure designed to prevent and/or reduce defects, such as an undesired short-circuit between power tap cells, and to improve integration and reliability.

According to some aspects of the inventive concepts, there is provided an integrated circuit device including a first cell region and a second cell region apart from each other in a first horizontal direction on a substrate and each including a plurality of cells arranged in a row in a second horizontal direction crossing the first horizontal direction, an inter-cell separation region extending lengthwise in the second horizontal direction between the first cell region and the second cell region, a first power line and a second power line overlapping the first cell region, the inter-cell separation region, and the second cell region in a vertical direction to the substrate and being apart from each other in a second horizontal direction crossing the first horizontal direction, a first power tap cell penetrating through the substrate in the vertical direction and connected to the first power line, a second power tap cell penetrating through the substrate in the vertical direction and connected to the second power line, a first dummy gate insulating line and a second dummy gate insulating line apart from each other in the first horizontal direction, with the first power tap cell and the second power tap cell therebetween, in the inter-cell separation region, and each extending in the second horizontal direction, and a dummy gate insulating bridge defining a vacuum space and connected to the first dummy gate insulating line and the second dummy gate insulating line.

According to some aspects of the inventive concepts, there is provided an integrated circuit device including a first cell region, an inter-cell separation region, and a second cell region sequentially arranged on a substrate in a first horizontal direction, a first power line and a second power line overlapping the first cell region, the inter-cell separation region, and the second cell region in a vertical direction to the substrate and being apart from each other in a second horizontal direction crossing the first horizontal direction, a first power tap cell penetrating through the substrate in the vertical direction and connected to the first power line, a second power tap cell penetrating through the substrate in the vertical direction and connected to the second power line, a first dummy gate insulating line and a second dummy gate insulating line apart from each other in the first horizontal direction, with the first power tap cell and the second power tap cell therebetween, in the inter-cell separation region, and each extending in the second horizontal direction, and a dummy gate insulating bridge defining a vacuum space and connected to the first dummy gate insulating line and the second dummy gate insulating line.

According to some aspects of the inventive concepts, there is provided an integrated circuit device including a first cell region and a second cell region apart from each other on a substrate in a first horizontal direction and each including a plurality of cells, an inter-cell separation region arranged between the first cell region and the second cell region on the substrate and extending lengthwise in a second horizontal direction crossing the first horizontal direction, a plurality of gate lines extending lengthwise in the second horizontal direction in each of the plurality of cells, a first dummy gate insulating line and a second dummy gate insulating line extending lengthwise in the second horizontal direction in the inter-cell separation region and being apart from each other in the first horizontal direction, a first power line and a second power line overlapping the first cell region, the inter-cell separation region, and the second cell region in a vertical direction to the substrate and being apart from each other in the second horizontal direction, a first inter-dummy gate insulating structure and second inter-dummy gate insulating structure arranged between the first dummy gate insulating line and the second dummy gate insulating line and being apart from each other in the second horizontal direction, a first power tap cell penetrating through the first inter-dummy gate insulating structure and the substrate in the vertical direction to the substrate and connected to the first power line, a first power tap cell penetrating through the second inter-dummy gate insulating structure and the substrate in the vertical direction to the substrate and connected to the second power line, and a dummy gate insulating bridge defining a vacuum space and connected to the first inter-dummy gate insulating structure, the second inter-dummy gate insulating structure, the first dummy gate insulating line, and the second dummy gate insulating line.

### BRIEF DESCRIPTION OF THE DRAWINGS

Embodiments will be more clearly understood from the following detailed description taken in conjunction with the accompanying drawings in which:

FIG. 1 is a plane layout diagram of some portions of an integrated circuit device according to some example embodiments;

FIG. 2 is a plane layout diagram for explaining an example of a configuration of a cell included in an integrated circuit device according to some example embodiments;

FIG. 3A is a cross-sectional view showing an enlarged cross-sectional portion of the configuration of FIG. 1 taken along line X1-X1′;

FIG. 3B is a cross-sectional view showing an enlarged cross-sectional portion of the configuration of FIG. 1 taken along line X2-X2′;

FIG. 3C is a cross-sectional view showing an enlarged cross-sectional portion of the configuration of FIGS. 1 and 2 taken along line Y1-Y1′;

FIG. 3D is a cross-sectional view showing an enlarged cross-sectional portion of the configuration of FIG. 1 taken along line Y2-Y2′;

FIGS. 4A to 12B are cross-sectional views illustrated according to a process order to explain a method of manufacturing an integrated circuit device according to some example embodiments, wherein FIGS. 4A, 5A, . . . , and 12A are enlarged cross-sectional views of portions corresponding to FIG. 1 taken along line X1-X1′, illustrated according to process order, FIGS. 4B, 5B, . . . , and 12B are enlarged cross-sectional views of some configurations taken along line X2-X2′ of FIG. 1 and illustrated according to a process order, and FIGS. 5C, 8C, 9C, and 11C are plan views of portions corresponding to FIG. 1 and illustrated according to a process order;

FIG. 13 is a layout diagram of a portion of an integrated circuit device according to some example embodiments;

FIG. 14 is a layout diagram of a portion of an integrated circuit device according to some example embodiments;

FIG. 15 is a layout diagram of a portion of an integrated circuit device according to some example embodiments;

FIG. 16 is a cross-sectional view of an integrated circuit device according to some example embodiments;

FIG. 17 is a cross-sectional view of an integrated circuit device according to some example embodiments;

FIG. 18 is a cross-sectional view of an integrated circuit device according to some example embodiments; and

FIGS. 19A and 19B are cross-sectional views of an integrated circuit device according to some example embodiments.

### DETAILED DESCRIPTION OF THE EMBODIMENTS

Hereinafter, embodiments are described in detail with reference to the accompanying drawings. The same reference numerals are used for the same components in the drawings, and redundant descriptions thereof are omitted.

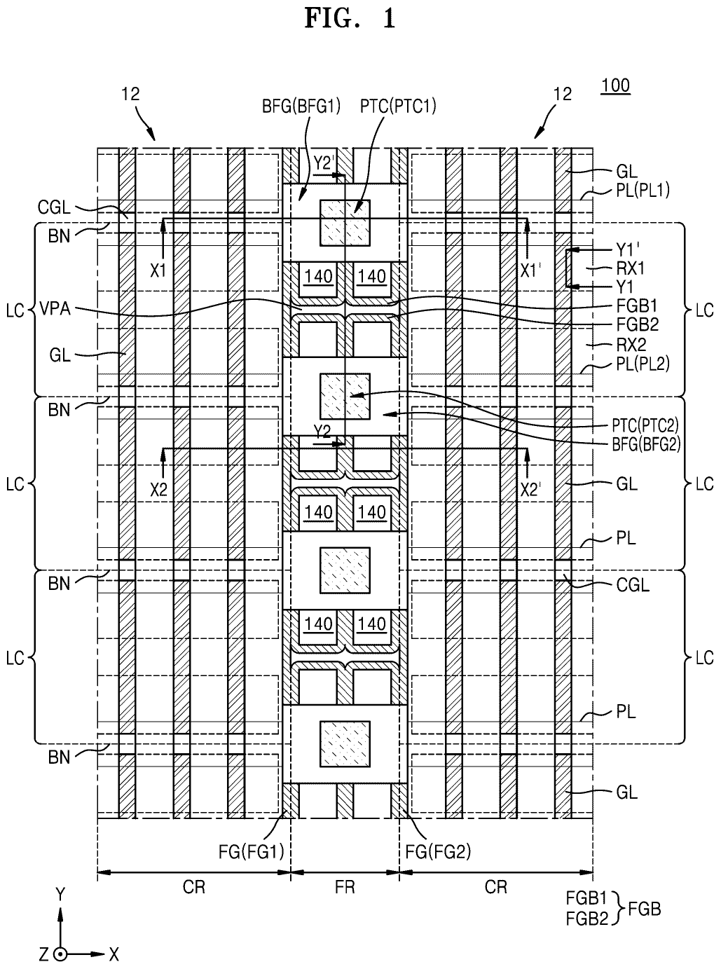

FIG. 1 is a plane layout diagram of some portions of an integrated circuit device 100 according to some example embodiments.

Referring to FIG. 1, the integrated circuit device 100 may include a plurality of cell regions CR apart from each other in a first horizontal direction (an X direction). The plurality of cell regions CR may each include a plurality of cells LC arranged in a row in a second horizontal direction (a Y direction) crossing the first horizontal direction (the X direction). The second horizontal direction (the Y direction) may be orthogonal to the first horizontal direction (the X direction). An inter-cell separation region FR may extend lengthwise in the second horizontal direction (the Y direction) between two cell regions CR adjacent in the first horizontal direction (the X direction) among the plurality of cell regions CR. Herein, the cell region CR arranged on a side of the first horizontal direction (the X direction) with respect to the inter-cell separation region FR is referred to as a first cell region, and the cell region CR arranged on the other side of the first horizontal direction (the X direction) with respect to the inter-cell separation region FR is referred to as a second cell region.

In each of the plurality of cells LC included in the plurality of cell regions, a plurality of gate lines GL may extend in the second horizontal direction (the Y direction). In the inter-cell separation region FR, a plurality of dummy gate insulating lines FG may extend along the second horizontal direction (the Y direction).

The cell region CR may include a plurality of cell blocks 12 including the plurality of cells LC. The cell block 12 may include the plurality of cell LCs including circuit patterns included in various circuits. The plurality of cells LC may be arranged in the cell block 12 in a matrix form along the first horizontal direction (the X direction) and the second horizontal direction (the Y direction).

A plurality of cells LC may include a circuit pattern having a layout designed according to a place and route (PnR) method to perform at least one logic function. A plurality of cells LC may perform various logic functions. In some example embodiments, the plurality of cells LC may include a plurality of standard cells. In some example embodiments, at least some of the plurality of cells LC may perform the same logic function. In some example embodiments, at least some of the plurality of cells LC may perform different logic functions from each other.

The plurality of cells LC may include various logic cells including a plurality of circuit devices. For example, the each of the plurality of cells LC may include AND, NAND, OR, NOR, exclusive OR (XOR), exclusive NOR (XNOR), inverter (INV), adder (ADD), buffer (BUF), delay (DLY), filter (FIL), multiplexer (MXT/MXIT), OR/AND/INVERTER (OAI), AND/OR (AO), AND/OR/INVERTER (AOI), D flip-flop, reset flip-flop, master-slave flip-flop, latch, or a combination thereof, but is not limited thereto.

The area of each of the plurality of cells LC in the integrated circuit device 100 may be limited by a cell boundary BN. At least some of the plurality of cells LC arranged in a row extending in the first horizontal direction (the X direction) in the cell block 12 may have the same width. At least some of the plurality of cells LC arranged in a row extending in the first horizontal direction (the X direction) in the cell block 12 may have the same height. However, the inventive concepts are not limited thereto. For example, at least some of the plurality of cells LC arranged in a row extending in the first horizontal direction (the X direction) in the cell block 12 may have different widths and/or heights from each other.

In some example embodiments, two adjacent cells LC among the plurality of cells LC arranged in a row extending in the first horizontal direction (the X direction) may be configured to have the same function. In this case, the two adjacent cells LC may have the same structure.

The integrated circuit device 100 may include a plurality of power lines PL. The plurality of power lines PL may extend across the plurality of cell regions CR and inter-cell separation region FR in the first horizontal direction (the X direction) and extend lengthwise in the first horizontal direction (the X direction). The plurality of power lines PL may be arranged in parallel to each other. The plurality of power lines PL may be configured to supply power to the plurality of cells LC arranged in a row extending in the first horizontal direction (the X direction) in the plurality of cell regions CR. The plurality of power lines PL may be configured to alternately supply different voltages in the second horizontal direction (the Y direction).

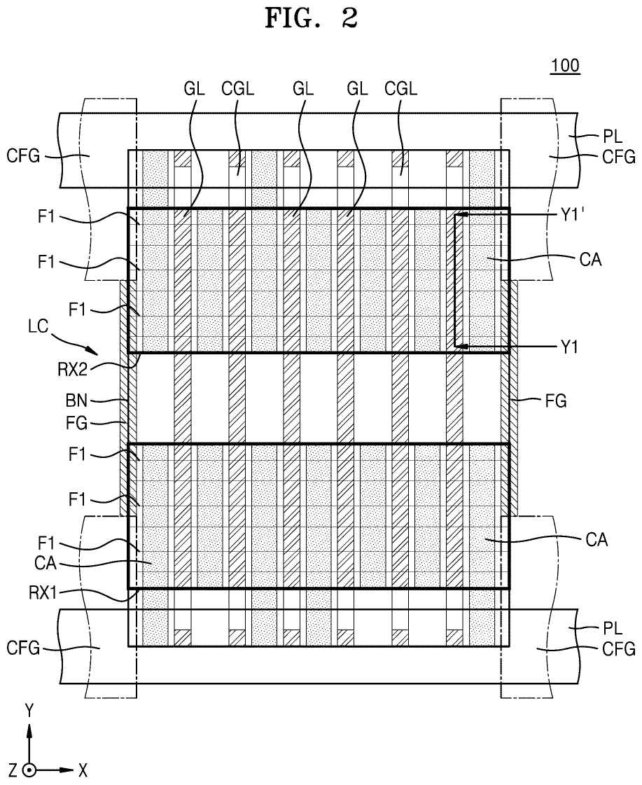

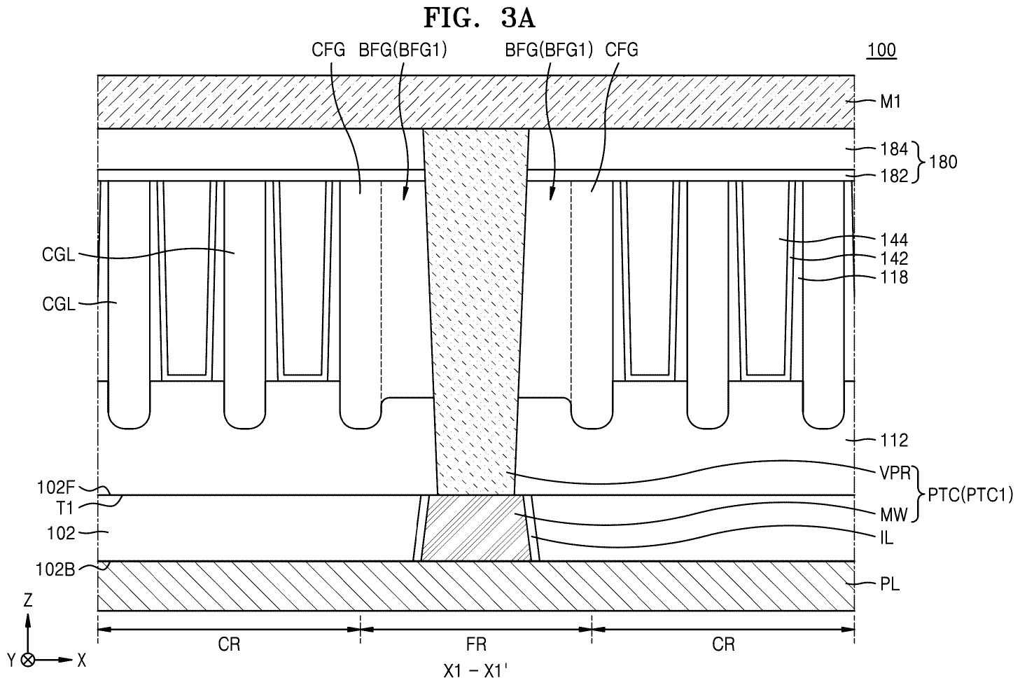

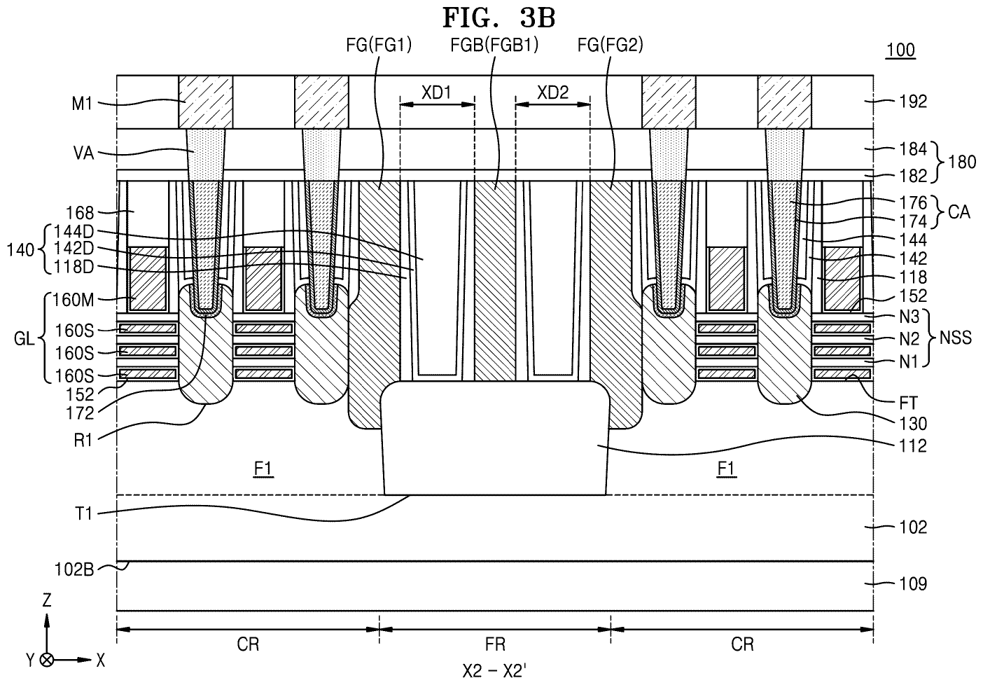

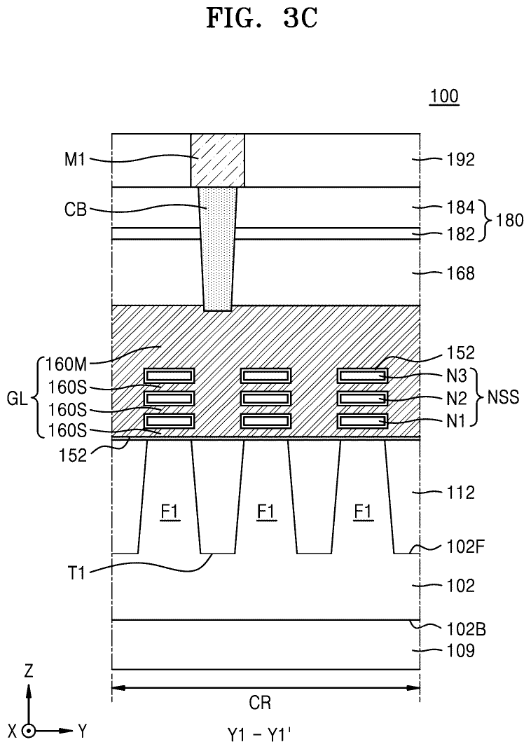

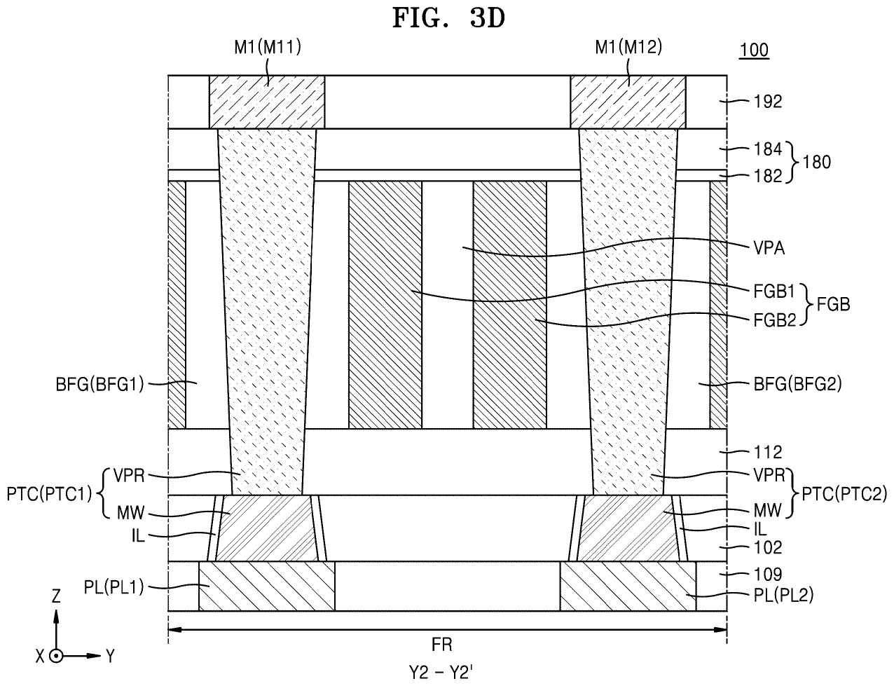

FIG. 2 is a plane layout diagram for explaining an embodiment of a configuration of any one of the plurality of cells LC illustrated in FIG. 1. FIG. 3A is a cross-sectional view showing an enlarged cross-sectional portion of the configuration of FIG. 1 taken along line X1-X1′. FIG. 3B is a cross-sectional view showing an enlarged cross-sectional portion of the configuration of FIG. 1 taken along line X2-X2′. FIG. 3C is a cross-sectional view showing an enlarged cross-sectional portion of the configuration of FIGS. 1 and 2 taken along line Y1-Y1′. FIG. 3D is a cross-sectional view showing an enlarged cross-sectional portion of the configuration of FIG. 1 taken along line Y2-Y2′. Referring to FIGS. 1, 2, and 3A to 3D, the integrated circuit device 100 including an active region in the form of a nanowire or a nanosheet and a field effect transistor having a gate-all-around structure, wherein a gate surrounds the active region, is described below. However, the inventive concepts are not limited thereto, and the integrated circuit device 100 may include a field effect transistor (FET) device based on a two-dimensional material, such as a planar FET device, a complementary FET (CFET), 3-Dimensional Stacked FET (3DSFET) device, a finFET device, or a MoS2 semiconductor gate electrode.

Referring to FIGS. 1, 2, and 3A to 3D, the integrated circuit device 100 may include the plurality of cells LC having a plane area limited by the cell boundary BN on a substrate 102. The substrate 102 may include a front side surface 102F and a backside surface 102B opposing each other.

As illustrated in FIG. 1, the plurality of power lines PL may be disposed on the backside surface 102B of the substrate 102. The plurality of power lines PL may include a portion overlapping, in a vertical direction (a Z direction), the cell boundary BN of each of the plurality of cells LC, the cell boundary BN being arranged in a row (a first row) selected from the plurality of cells LC and extending in the first horizontal direction (the X direction). The plurality of power lines PL may include a portion overlapping, in the vertical direction (the Z direction), the cell boundary BN of each of the plurality of cells LC, the cell boundary BN being arranged in another row (a second row) selected from the plurality of cells LC, extending in the first horizontal direction (the X direction), and adjacent to the first row. The plurality of power lines PL may include a portion overlapping the inter-cell separation region FR in the vertical direction (the Z direction).

The plurality of cells LC may each include a first device region RX1 and a second device region RX2. A plurality of fin-type active regions F1 protruding in the vertical direction (the Z direction) from the front side surface 102F of the substrate 102 may be arranged in each of the first element region RX1 and the second element region RX2. The plurality of fin-type active regions F1 may extend lengthwise and parallel to each other in the first horizontal direction (the X direction) in each of the first device region RX1 and the second device region RX2 of the cell LC.

The substrate 102 may include a semiconductor such as Si or Ge or a compound semiconductor such as SiGe, SiC, GaAs, InAs, InGaAs, or InP. The terms used herein, “SiGe,” “SiC,” “GaAs,” “InAs,” “InGaAs,” and “InP” refer to materials respectively including elements included in the terms, and are not formulas representing the stoichiometric relation between elements. The substrate 102 may include a conductive area, for example, a well doped with impurities or a structure doped with impurities.

Trench regions TI may be respectively limited between the plurality of fin-type active regions F1 in the first device region RX1 and the second device region RX2 of each of the plurality of cells LC, and the trench region Tl may be filled with a device isolation layer 112. In the cell region CR, the device isolation layer 112 may cover a portion of both side walls of each of the plurality of fin-type active regions F1 in the second horizontal direction (the Y direction). The device isolation layer 112 may include a silicon oxide layer, but is not limited thereto. The plurality of fin-type active regions F1 may protrude above the device isolation layer 112 as a fin shape in the first device region RX1 and the second device region RX2.

As illustrated in FIGS. 3A, 3B, and 3D, the device isolation layer 112 may cover the front side surface 102F of the substrate 102 in the cell region CR and the inter-cell separation region FR. As illustrated in FIG. 3B, a portion of the device isolation layer 112 in the inter-cell separation region FR may cover both side walls of each of the plurality of fin-type active regions F1 in the first horizontal direction (the X direction).

The plurality of gate lines GL may extend in the second horizontal direction (the Y direction) crossing the plurality of fin-type active regions F1 in the first device region RX1 and the second device region RX2 of each of the plurality of cells LC. The front side surface 102F of the substrate 102 may face the plurality of gate lines GL.

In some example embodiments, the first device region RX1 may be an NMOS transistor region, and a plurality of N-type metal-insulator-semiconductor (NMOS) transistors may be formed in portions wherein the fin-type active regions F1 cross the gate lines GL in the first device region RX1. The second device area RX2 may be a P-type metal-insulator-semiconductor (PMOS) transistor region, and a plurality of PMOS transistors may be formed in portions wherein the fin-type active regions F1 cross the gate lines GL in the second device region RX2.

As illustrated in FIGS. 3B and 3C, a plurality of nanosheet stacks NSS may be disposed on a fin upper surface FT of each of the plurality of fin-type active regions F1 in regions wherein the plurality of fin-type active regions F1 cross the plurality of gate lines GL. The plurality of nanosheet stacks NSS may include at least one nanosheet facing the fin upper surface FT in a position apart from the fin upper surface FT of the fin-type active region F1 in the vertical direction (the Z direction). It would be understood that the nanosheet includes nanowires.

The plurality of nanosheet stacks NSS may each include a first nanosheet N1, a second nanosheet N2, and a third nanosheet N3 overlapping each other in the vertical direction (the Z direction) above the fin-type active region F1. Vertical distances (the distance in the Z direction) between the first nanosheet N1, the second nanosheet N2, and the third nanosheet N3 and the fin upper surface FT of the fin-type active region F1 may be different from each other. The plurality of gate lines GL may respectively surround the first nanosheet N1, the second nanosheet N2, and the third nanosheet N3 included in the nanosheet stack NSS.

In some example embodiments, a configuration wherein the plurality of nanosheet stacks NSS and the plurality of gate lines GL are disposed on one fin-type active region F1 and the plurality of nanosheet stacks NSS are arranged in a row in the first horizontal direction (the X direction) on one fin-type active region F1 is described. However, the number of nanosheet stacks NSS and the number of gate lines GL disposed on one fin-type active region F1 are not particularly limited.

The first nanosheet N1, the second nanosheet N2, and the third nanosheet N3 included in the nanosheet stack NSS may each function as a channel region. In some example embodiments, the first nanosheet N1, the second nanosheet N2, and the third nanosheet N3 may have the same or substantially the same thickness along the vertical direction (the Z direction). In some example embodiments, at least a portion of the first nanosheet N1, the second nanosheet N2, and the third nanosheet N3 may have different thicknesses from each other along the vertical direction (the Z direction). In some example embodiments, the first nanosheet N1, the second nanosheet N2, and the third nanosheet N3 included in the nanosheet stack NSS may each include a Si layer, a SiGe layer, or a combination thereof.

As illustrated in FIG. 3B, the first nanosheet N1, the second nanosheet N2, and the third nanosheet N3 included in one nanosheet stack NSS may have the same or similar size in the first horizontal direction (the X direction). In some example embodiments, unlike the illustration in FIG. 3B, at least some portions of the first nanosheet N1, the second nanosheet N2, and the third nanosheet N3 included in one nanosheet stack NSS may have different sizes from each other. In some example embodiments, it is described that the plurality of nanosheet stacks NSS each include three nanosheets, but the inventive concepts are not limited thereto. For example, the nanosheet stack NSS may include at least one nanosheet, and the number of nanosheets included in the nanosheet stack NSS is not particularly limited.

As illustrated in FIGS. 3B and 3C, the plurality of gate lines GL may each include a main gate portion 160M and a plurality of subgate portions 160S. The main gate portion 160M may cover the upper surface of the nanosheet stack NSS and extend lengthwise in the second horizontal direction (the Y direction). The plurality of subgate portions 160S may be integrally connected to the main gate portion 160M and arranged between the first nanosheet N1, the second nanosheet N2, and the third nanosheet N3 and between the first nanosheet N1 and the fin-type active region F1. In the vertical direction (the Z direction), a thickness of each of the plurality of subgate portions 160s may be less than a thickness of the main gate portion 160M.

As illustrated in FIG. 3B, a plurality of recesses R1 may be formed on the fin-type active region F1. A vertical level of a lowest surface of each of the plurality of recesses R1 may be lower than a vertical level of the fin upper surface FT of the fin-type active region F1. A plurality of source/drain regions 130 may be arranged in the plurality of recesses R1. The plurality of source/drain regions 130 may be arranged in a position adjacent to at least one gate line GL selected from the plurality of gate lines GL. The plurality of source/drain regions 130 may each have surfaces facing the first nanosheet N1, the second nanosheet N2, and the third nanosheet N3 included in the nanosheet stack NSS adjacent to each of the source/drain regions 130. The plurality of source/drain regions 130 may each be in contact with the first nanosheet N1, the second nanosheet N2, and the third nanosheet N3 included in the nanosheet stack NSS adjacent to the each of the source/drain regions 130.

The plurality of source/drain regions 130 may each include a semiconductor epitaxial layer epitaxially grown from the surface of the fin-type active region F1 exposed in the plurality of recesses R1 and the surface of each of the first nanosheet N1, the second nanosheet N2, and the third nanosheet N3. In some example embodiments, the plurality of source/drain regions 130 may include an epitaxially grown Si layer, an epitaxially grown SiC layer, or a plurality of epitaxially grown SiGe layers. When the first device region RX1 is an NMOS transistor region and the second device region RX2 is a PMOS transistor region, the plurality of source/drain regions 130 in the first device region RX1 may include a Si layer doped with an n-type dopant or a SiC layer doped with an n-type dopant, and the plurality of source/drain regions 130 in the second device region RX2 may include a SiGe layer doped with a p-type dopant. The n-type dopant may be selected from phosphorus (P), arsenic (As), and antimony (Sb). The p-type dopant may be selected from boron (B) and gallium (Ga).

In some example embodiments, the plurality of source/drain regions in the first device region RX1 and the plurality of source/drain regions 130 in the second device region RX2 may have different shapes and sizes. The shape of each of the plurality of source/drain regions 130 is not limited to the examples illustrated in FIG. 3B, and the plurality of source/drain regions 130 having various shapes and sizes may be formed in the first device region RX1 and the second device region RX2.

The plurality of gate lines GL may each include a metal, a metal nitride, a metal carbide, or a combination thereof. The metal may be selected from Ti, W, Ru, Nb, Mo, Hf, Ni, Co, Pt, Yb, Tb, Dy, Er, Al, La and Pd. The metal nitride may be selected from TiN and TaN. The metal carbide may be TiAIC. In some example embodiments, the plurality of gate lines GL may each include a TiN layer, a stack structure of TiAIC/TiN, a stack structure of TiAIC/TiN/W, a stack structure of TiN/TaN/TiAIC/TiN/W, or TIN, or a stack structure of TiN/TaN/TiN/TiAIC/TiN/W, but are not limited thereto.

A gate dielectric layer 152 may be arranged between the nanosheet stack NSS and the gate line GL. In some example embodiments, the gate dielectric layer 152 may have a stack structure including an interface dielectric layer and a high dielectric layer. The interface dielectric layer may include a material layer having a dielectric constant of about or exactly 9 or less, for example, about or exactly 9 to about or exactly 7, or about or exactly 9 to about or exactly 1, such as a silicon oxide layer, a silicon oxynitride layer, or a combination thereof. In some example embodiments, the interface dielectric layer may be omitted. The high dielectric layer may include a material having a greater dielectric constant than that of the silicon oxide layer. For example, the high dielectric layer may have a dielectric constant of about or exactly 10 to about or exactly 25. The high dielectric layer may include hafnium oxide, but is not limited thereto.

As illustrated in FIGS. 3B and 3C, an upper surface of each of the gate dielectric layer 152 and gate line GL may be covered with a capping insulating pattern 168. The capping insulating pattern 168 may include a silicon nitride layer.

Both side walls of each of the gate line GL and the capping insulating pattern 168 may be covered with an insulating spacer 118. The insulating spacer 118 may cover both side walls of the main gate portion 160M on the plurality of nanosheet stacks NSS. The insulating spacer 118 may be apart from the gate line GL with the gate dielectric layer 152 therebetween. The insulating spacer 118 may include silicon nitride, silicon oxide, SiCN, SiBN, SION, SiOCN, SiBCN, SiOC, or a combination thereof. The terms used herein, “SiCN”, “SiBN”, “SiON”, “SiOCN”, “SiBCN”, and “SiOC” refer to materials respectively including elements included in the terms, and are not formulas representing the stoichiometric relation between elements.

A metal silicide layer 172 may be formed on each of the plurality of source/drain regions 130. The metal silicide layer 172 may include a metal including Ti, W, Ru, Nb, Mo, Hf, Ni, Co, Pt, Yb, Tb, Dy, Er, or Pd. For example, the metal silicide layer 172 may include titanium silicide, but is not limited thereto.

The plurality of source/drain regions 130, the plurality of metal silicide layers 172, and the plurality of insulating spacers 118 may be covered with an insulating liner 142 on the substrate 102. In some example embodiments, the insulating liner 142 may be omitted. An inter-gate insulating layer 144 may be arranged on the insulating liner 142. If the insulating liner 142 is omitted, the inter-gate insulating layer 144 may be in contact with the plurality of source/drain regions 130. The insulating spacer 118, the insulating liner 142, and the inter-gate insulating layer 144 may form an inter-gate insulating structure in the plurality of cells LC.

In some example embodiments, the insulating liner 142 may include silicon nitride, SiCN, SiBN, SION, SiOCN, SiBCN, or a combination thereof, but is not limited thereto. The inter-gate insulating layer 144 may include a silicon oxide layer but is not limited thereto.

Both side walls of each of the plurality of subgate portions 160S included in the plurality of gate lines GL may be apart from the source/drain region 130 with the gate dielectric layer 152 therebetween. The gate dielectric layers 152 may be arranged between the subgate portion 160S included in the gate line GL and the first nanosheet N1, the second nanosheet N2, and the third nanosheet N3, respectively, and between the subgate portion 160S included in the gate line GL and the source/drain region 130.

The plurality of nanosheet stacks NSS may respectively be disposed on the fin upper surfaces FT of the plurality of fin-type active regions F1 in regions in which the plurality of fin-type active regions F1 cross the plurality of gate lines GL, and may each face the fin upper surface FT of the fin-type active region F1 from a position apart from the fin-type active region F1. On the substrate 102, a plurality of nanosheet transistors may be formed in the portions in which the plurality of fin-type active regions F1 cross the plurality of gate lines GL.

As illustrated in FIGS. 1 and 3A, a plurality of gate cut insulating patterns CGL may be arranged in the cell boundary BN extending in the first horizontal direction (the X direction) of each of the plurality of cells CL in the cell block 12. The plurality of gate cut insulating patterns CGL may respectively be arranged on an extension of the plurality of gate lines GL. The plurality of gate cut insulating patterns CGL may extend in the second horizontal direction (the Y direction) across the cell boundary BN of each of a pair of cells CL adjacent in the second horizontal direction (the Y direction) in the cell block 12. The plurality of gate cut insulating patterns CGL between the pair of cells CL may be arranged in a straight row along the first horizontal direction (the X direction). In some example embodiments, the plurality of gate cut insulating patterns CGL may include a silicon nitride layer, but are not limited thereto.

As illustrated in FIGS. 1 and 3B, the plurality of dummy gate insulating lines FG may extend lengthwise along the second horizontal direction (the Y direction) on the front side surface 102F of the substrate 102 in the inter-cell separation region FR. The plurality of dummy gate insulating lines FG between a pair of cells LC apart from each other in the first horizontal direction (the X direction) with the inter-cell separation region FR of the plurality of dummy gate insulating lines FG therebetween may be arranged at a regular pitch P1 along the first horizontal direction (the X direction) together with the plurality of gate lines GL included in the plurality of cells LC. In the second horizontal direction (the Y direction), a length of each of the plurality of dummy gate insulating lines FG may be less than a length of at least one gate line GL among the plurality of gate lines GL included in the plurality of cells LC.

The plurality of dummy gate insulating lines FG may not include a portion overlapping the power line PL in the vertical direction (the Z direction). The plurality of dummy gate insulating lines FG arranged in a straight line along the second horizontal direction (the Y direction) of the plurality of dummy gate insulating lines FG may extend intermittently along the second horizontal direction (the Y direction).

As illustrated in FIGS. 1 and 3B, a plurality of dummy gate insulating lines FG may be arranged between a pair of cells LC apart from each other in the first horizontal direction (the X direction) with the inter-cell separation region FR therebetween. The plurality of dummy gate insulating lines FG may include a first dummy gate insulating line FG1 overlapping the cell boundary BN of one cell LC selected from the pair of cells LC in the vertical direction (the Z direction) and a second dummy gate insulating line FG2 overlapping the cell boundary BN the other cell LC selected from the pair of cells LC in the vertical direction (the Z direction).

As illustrated in FIG. 3B, the first dummy gate insulating line FG1 and the second dummy gate insulating line FG2 may each include a portion overlapping the fin-type active region F1 in the vertical direction (the Z direction). The lowest surface of each of the first dummy gate insulating line FG1 and the second dummy gate insulating line FG2 may be closer to the substrate 102 than the fin upper surface FT of the fin-type active region F1 is to the substrate 102. The first dummy gate insulating line FG1 and the second dummy gate insulating line FG2 may each include a portion being in contact with the device isolation layer 112. In the inter-cell separation region FR, the device isolation layer 112 may include a portion between the substrate 102 and the plurality of dummy gate insulating lines FG.

As illustrated in FIG. 1, a length of each of the plurality of dummy gate insulating lines FG in the second horizontal direction (the Y direction) arranged between a pair of cells LC apart from each other in the first horizontal direction (the X direction) with the inter-cell separation region FR therebetween may be less than a length of at least one gate line GL of the plurality of gate lines GL included in the pair of cells LC. In some example embodiments, the lengths in the second horizontal direction (the Y direction) of the plurality of dummy gate insulating lines FG arranged between the pair of cells LC apart from each other in the first horizontal direction (the X direction) may be the same as or similar with each other. In some example embodiments, at least some of the plurality of dummy gate insulating lines FG arranged between the pair of cells LC apart from each other in the first horizontal direction (the X direction) may have different lengths in the second horizontal direction (the Y direction).

In some example embodiments, the plurality of dummy gate insulating lines FG are arranged between the pair of cells LC apart from each other in the first horizontal direction (the X direction) with the inter-cell separation region FR therebetween, but the inventive concepts are not limited thereto. For example, at least three dummy gate insulating lines FG may be arranged between the pair of cells LC apart from each other in the first horizontal direction (the X direction) with the inter-cell separation region FR therebetween.

As illustrated in FIGS. 1 and 3A, a plurality of bridge insulating patterns BFG may be arranged in the inter-cell separation region FR. The plurality of bridge insulating patterns BFG may be apart from each other in the second horizontal direction (the Y direction) and be arranged in a straight row along the second horizontal direction (the Y direction). A width of the bridge insulating pattern BFG In the first horizontal direction (the X direction) may be greater than a width of each of the plurality of dummy gate insulating lines FG.

As illustrated in FIG. 1, the plurality of bridge insulating patterns BFG may be respectively arranged on extensions of the cell boundaries BN along the first horizontal direction (the X direction) of the plurality of cells LC. As illustrated in FIGS. 1, 3A and 3D, each of the plurality of bridge insulating patterns BFG may be arranged in a position overlapping the power line PL in the vertical direction (the Z direction).

At least one dummy gate insulating line FG may be arranged between each of the plurality of bridge insulating patterns BFG. FIG. 1 illustrates a configuration in which two dummy gate insulating lines FG are arranged between each of the plurality of bridge insulating patterns BFG. The plurality of bridge insulating patterns BFG may respectively be in contact with the ends of the plurality of dummy gate insulating lines FG adjacent thereto.

As illustrated in FIGS. 1, 3A, and 3D, the plurality of bridge insulating patterns BFG may each include a bridge insulating edge portion CFG arranged on an extension of the cell boundary BN along the second horizontal direction (the Y direction) of the cell LC. The bridge insulating edge portion CFG of the bridge insulating pattern BFG may be in contact with at least one dummy gate insulating line FG. For example, the bridge insulating edge portion CFG of the bridge insulating pattern BFG may be in contact with at least one of the first dummy gate insulating line FG1 and the second dummy gate insulating line FG2, the first dummy gate insulating line FG1 and the second dummy gate insulating line FG1 being arranged along the second horizontal direction (the Y direction) of the cell LC and overlapping the cell boundary BN in the vertical direction (the Z direction). The bridge insulating edge portion CFG may extend along a straight line in the second horizontal direction (the Y direction) together with the first dummy gate insulating line FG1 or the second dummy gate insulating line FG2.

The inter-cell separation region FR may include a dummy gate insulating bridge FGB including a vacuum space VPA thereinside and connecting adjacent bridge insulating patterns BFG1 and BFG3 (also referred to as the first bridge insulating pattern FBG1 and a third bridge insulating pattern BFG3) among the plurality of bridge insulating patterns BFG and adjacent dummy gate insulating lines FG1 and FG2 (also referred to as the first dummy gate insulating line FG1 and the second dummy gate insulating line FG2) among the plurality of dummy gate insulating lines FG. The dummy gate insulating bridge FGB may include the same material as the dummy gate insulating line FG. The dummy gate insulating bridge FGB may be in contact with an upper surface of the device isolation layer 112.

The vacuum space VPA may be arranged in a central region of the dummy gate insulating bridge FGB. That is, a central region of the dummy gate insulating bridge FGB may define the vacuum space VPA. The dummy gate insulating bridge FGB may have a symmetrical shape with respect to the center of the vacuum space VPA. For example, the dummy gate insulating bridge FGB may have a symmetrical shape with respect to the center of the vacuum space VPA in any one of the first horizontal direction (the X direction) and the second horizontal direction (the Y direction). The vacuum space VPA may include a first tapered region of which a width is decreased toward a direction away from the center of the vacuum space VPA, and a second tapered region of which a width is increased toward a direction away from the center of the vacuum space VPA. In an embodiment, the vacuum space VPA may have the greatest width from the center of the vacuum space VPA to any one of the first horizontal direction (the X direction) and the second horizontal direction (the Y direction). In FIG. 1, the vacuum space VPA is illustrated as having the greatest width in the first horizontal direction (the X direction). However, the inventive concepts are not limited thereto. The vacuum space VPA may have the greatest width in the second horizontal direction (the Y direction).

The dummy gate insulating bridge FGB may include the first bridge insulating pattern BFG1, a dummy gate insulating bridge FGB1 and a second bridge insulating pattern BFG2 connected to the first dummy gate insulating line FG1 and the second dummy gate insulating line FG2, and a second dummy gate insulating bridge FGB2 connected to the first dummy gate insulating line FG1 and the second dummy gate insulating line FG2. In addition, the vacuum space VPA may be arranged between the first dummy gate insulating bridge FGB1 and the second dummy gate insulating bridge FGB2.

The first dummy gate insulating bridge FGB1 and the second dummy gate insulating bridge FGB2 may be completely apart from and not be in contact with each other due to the vacuum space VPA. The second dummy gate insulating bridge FGB2, the vacuum space VPA, and the first dummy gate insulating bridge FGB1 may be sequentially arranged in the second horizontal direction (the Y direction). The first dummy gate insulating bridge FGB1 and the second dummy gate insulating bridge FGB2 may have a round surface. For example, in a planar view including the first horizontal direction (the X direction) and the second horizontal direction (the Y direction), the first dummy gate insulating bridge FGB1 and the second dummy gate insulating bridge FGB2 may have a line convex toward the vacuum space VPA.

Since the dummy gate insulating bridge FGB including the vacuum space VPA is arranged between a first power tap cell PTC1 and a second power tap cell PTC2 to which different voltages are applied, a parasitic capacitor between the first power tap cell PTC1 and the second power tap cell PTC2 may be reduced. In addition, due to a location of the vacuum space VPA, even if an interval between the first power tap cell PTC1 and the second power tap cell PTC2 is narrow, the first power tap cell PTC1 and the second power tap cell PTC2 may be prevented or have reduce occurrences from being electrically short-circuited.

In some example embodiments, unlike the illustration of FIG. 1, the bridge insulating pattern BFG is not in direct contact with at least one of the first dummy gate insulating line FG1, the second dummy gate insulating line FG2, and the dummy gate insulating bridge FGB and another insulating layer may be arranged therebetween.

As illustrated in FIGS. 3A and 3D, a bottom surface of the bridge insulating pattern BFG facing the substrate 102 may be in contact with the device isolation layer 112. In the inter-cell separation region FR, the device isolation layer 112 may include a portion between the substrate 102 and the plurality of bridge insulating patterns BFG. A portion of the device isolation layer 112 may be exposed to the vacuum space VPA. For example, a portion of the upper surface of the device isolation layer 112 may be exposed to the vacuum space VPA. From a different view, an interval between the substrate 102 and the vacuum space VPA may be the same or substantially the same as an interval between the substrate 102 and the gate line GL included in any one of the plurality of cells. In some example embodiments, the dummy gate insulating line FG, the bridge insulating pattern BFG, and the dummy gate insulating bridge FGB may each include a silicon nitride layer, but are not limited thereto.

As illustrated in FIG. 1, a width of the bridge insulating pattern BFG in the second horizontal direction (the Y direction) may be greater than a width of the power line PL. In some example embodiments, unlike the illustration of FIG. 1, in the second horizontal direction (the Y direction), the bridge insulating pattern BFG may include a portion having the same width as the power line PL or a portion having a lesser width than the power line PL. In FIG. 1, the planar shape of the bridge insulating pattern BFG is illustrated as being a rectangular or roughly rectangular, but the inventive concepts are not limited thereto. For example, the planar shape of the bridge insulating pattern BFG may have various shapes such as oval, rhombus, or an irregular polygon.

A width of the dummy gate insulating line FG may not be constant. For example, the width of a region of the dummy gate insulating line FG exposed to the vacuum space VPA may be less than the width of a region of the dummy gate insulating line FG that is not exposed to the vacuum space VPA. If the dummy gate insulating line FG is not exposed to the vacuum space VPA, the width of the dummy gate insulating line FG may be constant. For example, the width of the dummy gate insulating line FG may be the same or substantially the same as the width of the gate line GL.

As illustrated in FIG. 3B, in the inter-cell separation region FR, an inter-dummy gate insulating structure 140 may be arranged between the plurality of dummy gate insulating lines FG and the dummy gate insulating bridge FGB. The inter-dummy gate insulating structure 140 may be surrounded by the bridge insulating pattern BFG, the plurality of dummy gate insulating lines FG, and the dummy gate insulating bridge FGB. The inter-dummy gate insulating structure 140 may include a dummy insulating spacer 118D, a dummy insulating liner 142D, and an inter-dummy gate insulating layer 144D. Detailed configurations of the dummy insulating spacer 118D, the dummy insulating liner 142D, and the inter-dummy gate insulating layer 144D may be mostly the same as the descriptions regarding the insulating spacer 118, the insulating liner 142, and the inter-gate insulating layer 144 arranged in the cell LC. The dummy insulating spacer 118D, the dummy insulating liner 142D, and the inter-dummy gate insulating layer 144D may include the same materials as those of the insulating spacer 118, the insulating liner 142, and the inter-gate insulating layer 144 arranged in the cell LC. That is, the insulating spacer 118 and the dummy insulating spacer 118D may include the same material, the insulating liner 142 and the dummy insulating liner 142D may include the same material, and the inter-gate insulating layer 144 and the inter-dummy gate insulating layer 144D may include the same material. The inter-dummy gate insulating structure 140 may include a portion in contact with the bridge insulating pattern BFG.

As illustrated in FIGS. 3B and 3D, in the inter-cell separation region FR, the device isolation layer 112 may include a portion arranged between the inter-dummy gate insulating structure 140 and the substrate 102. In the inter-cell separation region FR, the inter-dummy gate insulating structure 140 may be in contact with the upper surface of the device isolation layer 112. The vacuum space VPA may expose a portion of the upper surface of the device isolation layer 112.

As illustrated in FIGS. 1 and 3A, a plurality of via power rails VPR may be arranged in the inter-cell separation region FR. Each of the plurality of via power rails VPR may be arranged in the inter-cell separation region FR on an extension of the cell boundary BN along the first horizontal direction (the X direction) of the plurality of cells LC.

As illustrated in FIG. 1, the plurality of via power rails VPR may be apart from each other in the second horizontal direction (the Y direction) and may be arranged in a straight row along the second horizontal direction (the Y direction). However, the inventive concepts are not limited thereto. For example, the plurality of via power rails VPR may be arranged in zigzags wherein some of the plurality of via power rails VPR are arranged along a first straight line extending in the second horizontal direction (the Y direction) and the other via power rails VPR are arranged along a second straight line extending in the second horizontal direction (the Y direction) and apart from the first straight line in the first horizontal direction (the X direction).

As illustrated in FIG. 3A, each of the plurality of via power rails VPR may penetrate through one bridge insulating pattern BFG selected from the plurality of bridge insulating patterns BFG in the vertical direction (the Z direction) and penetrate through the device isolation layer 112 in the vertical direction (the Z direction) to be connected to one power line PL selected from the plurality of power lines PL. The vertical level of the upper surface of the via power rail VPR farthest from the substrate 102 may be farther from the substrate 102 than the vertical level of the upper surface of the bridge insulating pattern BFG farthest from the substrate 102 is from the substrate 102.

In some example embodiments, the plurality of via power rails VPR may each include a metal plug and a conductive barrier layer surrounding the metal plug. The metal plug may include Mo, Co, Cu, W, Ru, Mn, Ti, Ta, Al, a combination thereof, or an alloy thereof. The conductive barrier layer may include Ti, TiN, Ta, TaN, or a combination thereof. In some example embodiments, each side wall of the plurality of via power rails VPR may be surrounded by via insulating spacers. The via insulating spacer may include a Si oxide layer, a Si nitride layer, a Si oxynitride layer, or a combination thereof.

As illustrated in FIG. 3B, a plurality of source/drain contacts CA may be disposed on the plurality of source/drain regions 130. Each of the plurality of source/drain contacts CA may be in contact with the metal silicide layer 172 by penetrating through the inter-gate insulating layer 144 and the insulating liner 142 in the vertical direction (the Z direction). Each of the plurality of source/drain contacts CA may be electrically connected to the source/drain region 130 through the metal silicide layer 172. Each of the plurality of source/drain contacts CA may be apart from the main gate portion 160M in the first horizontal direction (the X direction) with the insulating spacer 118 therebetween.

The plurality of source/drain contacts CA may include a conductive barrier layer 174 and a contact plug 176 sequentially stacked on the source/drain region 130. The conductive barrier layer 174 may cover a bottom surface and sidewalls of the contact plug 176 and may be in contact with the bottom surface and the side walls of the contact plug 176. The plurality of source/drain contacts CA may include a portion surrounded by the inter-gate insulating layer 144 and extending lengthwise in the vertical direction (the Z direction). The conductive barrier layer 174 may be arranged between the metal silicide layer 172 and the contact plug 176. The conductive barrier layer 174 may have a surface in contact with the metal silicide layer 172 and a surface in contact with the contact plug 176. In some example embodiments, the conductive barrier layer 174 may include metal or metal nitride. For example, the conductive barrier layer 174 may include Ti, Ta, W, TiN, TaN, WN, WCN, TiSiN, TaSIN, WSiN, or a combination thereof, but is not limited thereto. The contact plug 176 may include molybdenum (Mo), copper (Cu), tungsten (W), cobalt (Co), ruthenium (Ru), manganese (Mn), titanium (Ti), tantalum (Ta), aluminum (Al), a combination thereof, or an alloy thereof, but is not limited thereto.

As illustrated in FIGS. 3B and 3C, upper surfaces of the plurality of source/drain contacts CA, the plurality of capping insulating patterns 168, and the inter-gate insulating layer 144 may be covered with an upper insulating structure 180. The upper insulating structure 180 may include an etch stop layer 182 and an upper insulating layer 184 sequentially stacked on each of the plurality of source/drain contacts CA, the plurality of capping insulating patterns 168, and the inter-gate insulating layer 144. The etch stop layer 182 may include SiC, SiN, nitrogen-doped silicon carbide (SiCN), SiOC, AlN, AION, AIO, AlOC, or a combination thereof. The upper insulating layer 184 may include an oxide layer, a nitride layer, an ultra low-k layer having an ultra low dielectric constant K of about or exactly 2.2 to about or exactly 2.4, or a combination thereof. For example, the upper insulating layer 184 may include a tetraethylorthosilicate (TEOS) layer, a high density plasma (HDP) oxide layer, a boro-phospho-silicate glass (BPSG) layer, a flowable chemical vapor deposition (FCVD) layer, a SiON layer, a SiN layer, a SiOC layer, a SiCOH layer, or a combination thereof, but is not limited thereto.

As illustrated in FIG. 3B, a plurality of source/drain via contacts VA may be disposed on the plurality of source/drain contacts CA. Each of the plurality of source/drain via contacts VA may penetrate through the upper insulating structure 180 to be in contact with the source/drain contact CA. Each of the plurality of source/drain regions 130 may be electrically connected to the source/drain via contact VA through the metal silicide layer 172 and the source/drain contact CA. A bottom surface of each of the plurality of source/drain via contacts VA may be in contact with the upper surface of the source/drain via contact CA. Each of the plurality of source/drain via contacts VA may include a meta layer and a conductive barrier layer surrounding the metal layer. The metal layer may include Mo, Co, Cu, W, Ru, Mn, or a combination thereof. The conductive barrier layer 174 may include Ti, Ta, W, TiN, TaN, WN, WCN, TiSiN, TaSIN, WSiN, or a combination thereof, but is not limited thereto. The conductive barrier layer 174 may be omitted in each of the plurality of source/drain via contacts VA.

As illustrated in FIG. 3C, a gate contact CB may be disposed on the gate line GL. The gate contact CB may penetrate through the upper insulating structure 180 and the capping insulating pattern 168 in the vertical direction (the Z direction) to be connected to the gate line GL. The bottom surface of the gate contact CB may be in contact with the upper surface of the gate line GL. The gate contact CB may include a metal layer and a conductive barrier layer surrounding the metal layer. The metal layer may include Mo, Co, Cu, W, Ru, Mn, or a combination thereof. The conductive barrier layer 174 may include Ti, Ta, W, TiN, TaN, WN, WCN, TiSiN, TaSIN, WSiN, or a combination thereof, but is not limited thereto. The conductive barrier layer 174 may be omitted in the gate contact CB.

As illustrated in FIG. 3A, the via power rail VPR may penetrate through the upper insulating structure 180 in the vertical direction (the Z direction). The upper surface of the via power rail VPR may be coplanar with the upper surface of the upper insulating structure 180. The plurality of source/drain contacts CA, the plurality of source/drain via contacts VA, and the gate contact CB may each be apart from the plurality of via power rails VPR in the horizontal direction, and the plurality of source/drain contacts CA, the plurality of source/drain via contacts CA, and the gate contact CB may not each include a portion overlapping the plurality of power lines PL in the vertical direction (the Z direction).

As illustrated in FIGS. 3A, 3B, and 3C, an interlayer insulating layer 192 may be disposed on each of the upper insulating structure 180, the plurality of source/drain via contacts VA, the gate contact CB, and the plurality of via power rails VPR. Materials included in the interlayer insulating layer 192 is generally the same as described with regard to the materials included in the upper insulating layer 184.

A plurality of upper wiring layers M1 may penetrate through the interlayer insulating layer 192. The plurality of upper wiring layers M1 may each be connected to one selected from the plurality of source/drain via contacts VA, the plurality of gate contacts CB, and the plurality of via power rails VPR. The plurality of via power rails VPR may each be connected to the source/drain via contact VA through at least one upper wiring layer M1 selected from the plurality of upper wiring layers M1. The plurality of upper wiring layers M1 may include Co, Cu, W, Ru, Mn, Ti, Ta, Al, a combination thereof, or an alloy thereof, but are not limited thereto.

One source/drain via contact VA selected from the plurality of source/drain via contacts VA may be connected between the source/drain contact CA and the upper wiring layer M1 in a location apart from the via power rail VPR in the horizontal direction. Among the plurality of source/drain regions 130, the source/drain region 130 connected to the via power rail VPR may be electrically connected to the via power rail VPR through the source/drain contact CA, the source/drain via contact VA, and the upper wiring layer M1.

As illustrated in FIG. 3A, a backside power rail MW may penetrate through the substrate 102 in the vertical direction (the Z direction) from the backside surface 102B of the substrate 102. The backside power rail MW may be arranged between the via power rail VPR and the power line PL, and, according to some example embodiments wherein a portion being in contact with the via power rail VPR and a portion being in contact with the power line PL may be included, the backside power rail MW may include a metal plug and a conductive barrier layer surrounding the metal plug. The metal plug may include Mo, Co, Cu, W, Ru, Mn, Ti, Ta, Al, a combination thereof, or an alloy thereof. The conductive barrier layer may include Ti, TIN, Ta, TaN, or a combination thereof. The side walls of the backside power rail MW may be surrounded by the backside insulating spacer IL. The backside power rail MW may be apart from the substrate 102 with an insulating spacer IL therebetween. The backside insulating spacer may include a Si oxide layer, a Si oxynitride layer, a Si nitride layer, or a combination thereof, but is not limited thereto. As illustrated in FIGS. 3B and 3C, the backside surface 102B of the substrate 102 may be covered with a backside insulating layer 109. The backside insulating layer 109 may include a Si oxide layer, a Si nitride layer, a Si carbide layer, a low dielectric layer, or a combination thereof. The low dielectric layer may include a fluorine-doped Si oxide, an organosilicate glass, a carbon-doped oxide, a porous silicon oxide, a porous organosilicate glass, a spin-on organic polymeric dielectric, a spin-on silicon based polymeric dielectric, or a combination thereof, but is not limited thereto.

The plurality of power lines PL may penetrate through the backside insulating layer 109 in the vertical direction (the Z direction) and may be in contact with an end of the backside power rail MW. The plurality of power lines PL may each be connected to the via power rail VPR through the backside power rail MW. The plurality of power lines PL may include a first power line PL1 and a second power line PL2 spaced apart from each other in the second horizontal direction (the Y direction).

As illustrated in FIGS. 1 and 3D, the backside power rail MW and the via power rail VPR may together be referred to as a power tap cell PTC. The plurality of power tap cells PTC may be apart from each other in the second horizontal direction (the Y direction) in the inter-cell separation region FR. For example, the power tap cell PTC may include the first power tap cell PTC1 configured to receive a first voltage from the first power line PL1 and provide the first voltage to the first device region RX1, and the second power tap cell PTC2 configured to receive a second voltage from the first power line PL1 and provide the second voltage to the second device region RX2. The first voltage and the second voltage may be different from each other. For example, when the first device region RX1 is an NMOS transistor region, the first power tap cell PTC1 may apply a ground voltage VSS to the first device region RX1, and when the second device region RX2 is a PMOS transistor region, the second power tap cell PTC2 may apply a power voltage VDD to the second device region RX2.

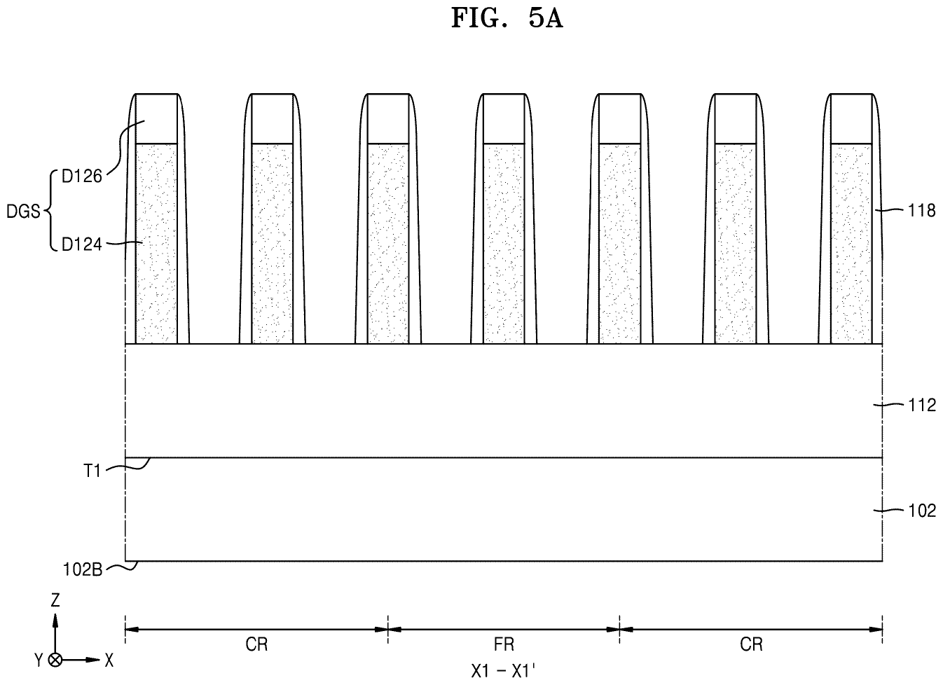

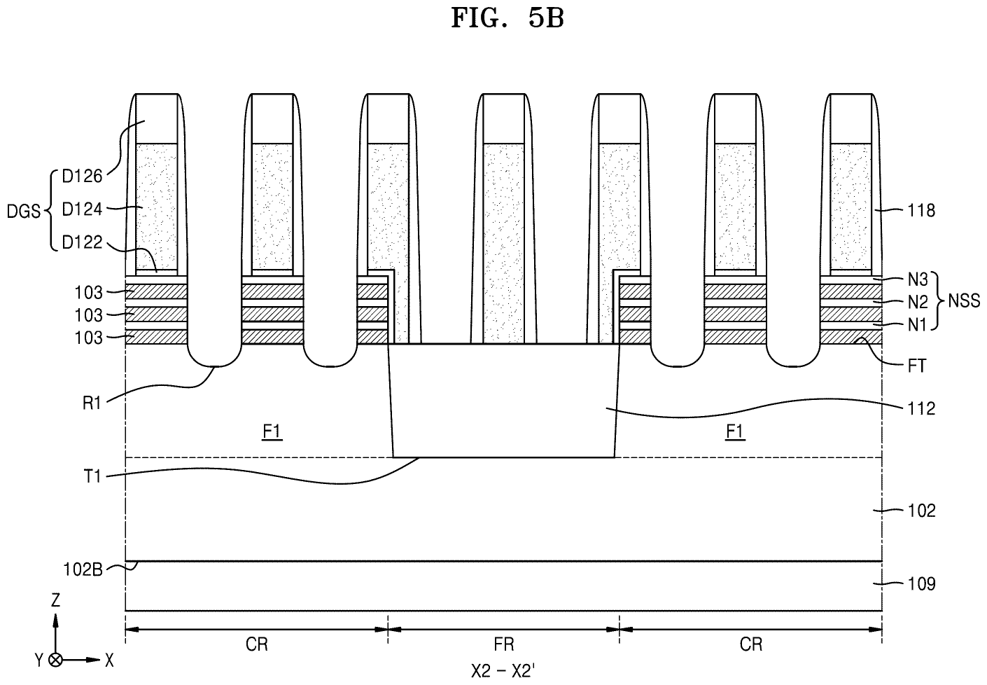

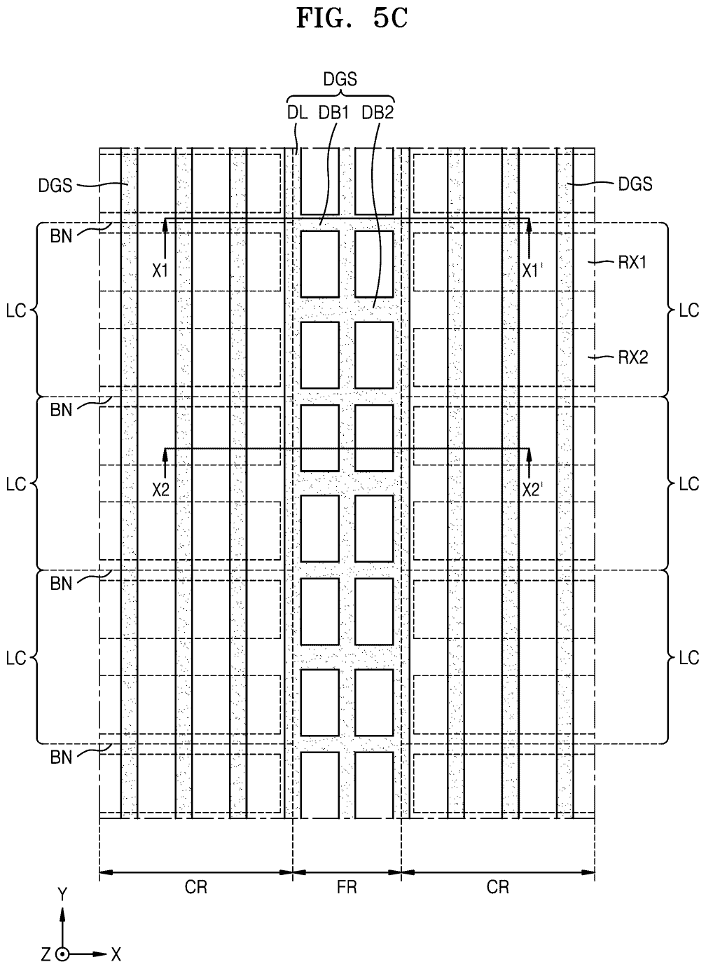

In the integrated circuit device 100 described with reference to FIGS. 1 to 3D, the plurality of dummy gate insulating lines FG may extend lengthwise in the second horizontal direction (the Y direction) in the inter-cell separation region FR, and, among the plurality of dummy gate insulating lines FG, the length in the vertical direction (the Z direction) of each of the plurality of dummy gate insulating lines FG between a pair of cells LC apart from each other in the first horizontal direction (the X direction) with the inter-cell separation region FR therebetween may be less than the length in the second horizontal direction (the Y direction) of at least one gate line GL among the plurality of gate lines GL in the pair of cells LC. Accordingly, during the manufacturing of the integrated circuit device 100, line patterns, that is, an intermediate structure required to form the plurality of dummy gate insulating lines FG, may be prevented or be reduced from being bent or tilted in an undesired direction due to stress from the surrounding environment, and the surrounding structures, for example, the plurality of dummy gate structures DGS (see FIGS. 5A to 5C), which are intermediate structures required for forming the gate line GL, may be prevented or reduced from being adversely affected by the structural defect of the line patterns, thereby preventing or reducing defects such as undesired short-circuit or disconnection between lines during the manufacturing process of the integrated circuit device 100 from occurring. In this regard, the integrated circuit device 100 according to an inventive concept may have a structure obtainable through stable processes, thereby improving the integration and reliability of the integrated circuit device 100.

Next, examples of manufacturing methods of an integrated circuit device according to some example embodiments will be described.

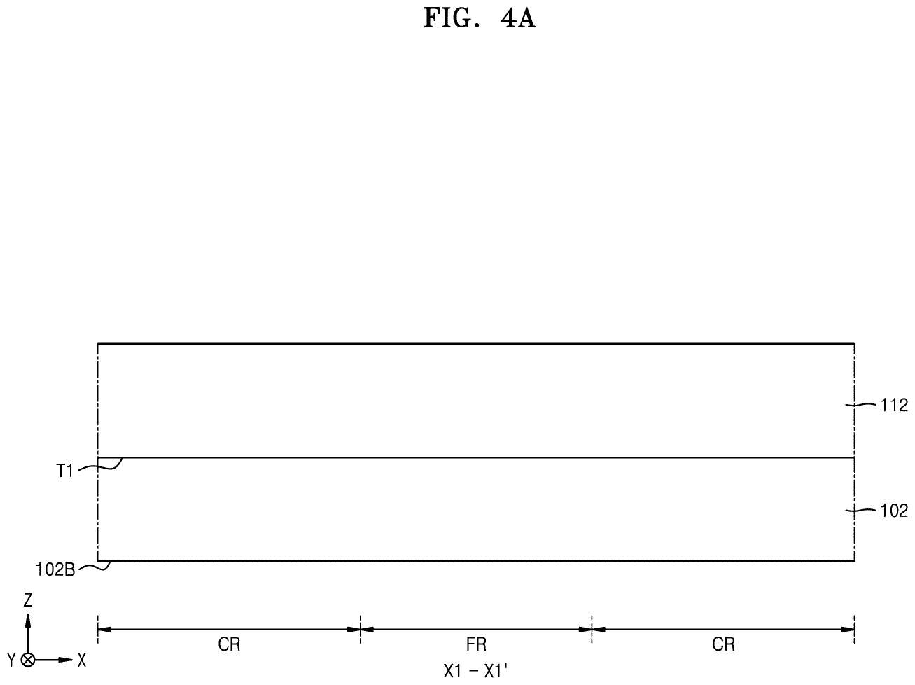

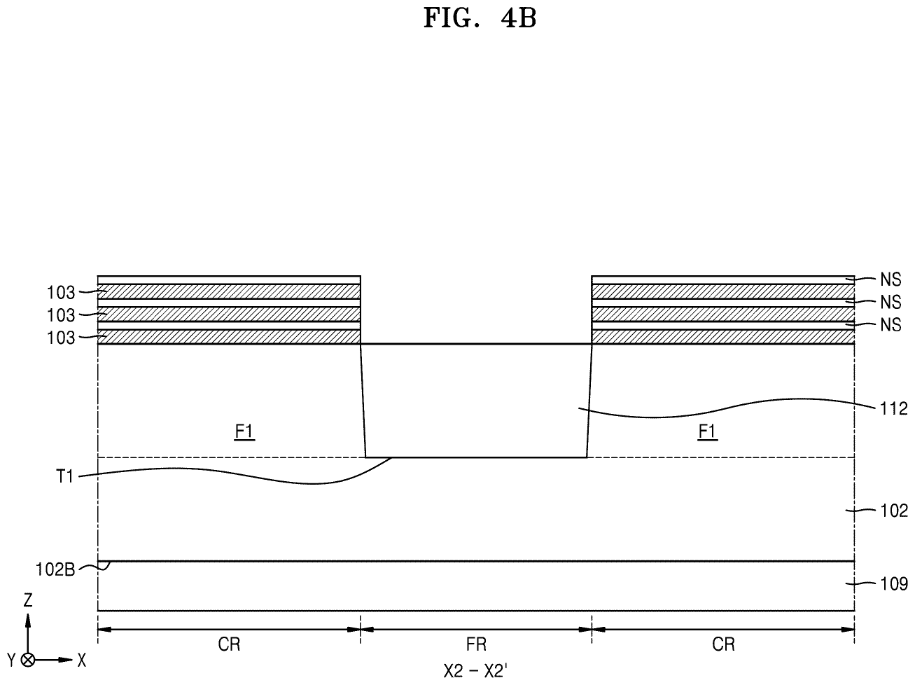

FIGS. 4A to 12B are cross-sectional views illustrated according to a process order to describe a method of manufacturing an integrated circuit device, according to some example embodiments. More particularly, FIGS. 4A, 5A, . . . , and 12A are enlarged cross-sectional views of some configurations taken along line X1-X1′ of FIG. 1 and illustrated according to a process order. More particularly, FIGS. 4B, 5B, . . . , and 12B are enlarged cross-sectional views of some configurations taken along line X2-X2′ of FIG. 1 and illustrated according to a process order. FIGS. 5C, 8C, 9C, and 11C are plan views of portions corresponding to FIG. 1 and illustrated according to a process order. Referring to FIGS. 4A to 12B, an example of a method of manufacturing the integrated circuit device 100 explained with reference to FIGS. 1 to 3C will be described. In FIGS. 4A to 12B, the same reference numerals with those of FIGS. 1 to 3C refer to the same elements, and detailed descriptions thereof are omitted.

Referring to FIGS. 4A and 4B, a plurality of sacrificial semiconductor layers 103 and a plurality of nanosheet semiconductor layers NS may be alternately stacked on the whole surface of the substrate 102 including the plurality of cell regions CR and the inter-cell separation region FR arranged between each of the plurality of cell regions CR.

The plurality of sacrificial semiconductor layers 103 and the plurality of nanosheet semiconductor layers NS may include semiconductor materials with different etching selectivity. In some example embodiments, the plurality of sacrificial semiconductor layers 103 may include a SiGe layer, and the plurality of nanosheet semiconductor layers NS may include a Si layer. In some example embodiments, Ge content may be constant in the plurality of sacrificial semiconductor layers 103. The SiGe layer included in the plurality of sacrificial semiconductor layers 103 may have a certain Ge content selected within a range of about or exactly 5 atom % to about or exactly 60 atom %, for example, about or exactly 10 atom % to about or exactly 40 atom %. Atom % refers to the atomic percentage of an element in a compound, for example, a Ge content of 5 atom % would mean 5% of the atoms would be Ge. The Ge content in the SiGe layer included in the plurality of sacrificial semiconductor layers 103 may be selected as necessary.

Then, by using a mask pattern (not shown) as an etching mask, portions of the plurality of sacrificial semiconductor layers 103, the plurality of nanosheet semiconductor layers NS, and the substrate 102 may be etched to respectively form the plurality of fin-type active regions F1 in the plurality of cell regions CR on the substrate 102. By forming the plurality of fin-type active regions F1, the plurality of trench regions TI may be defined on the substrate 102 in the plurality of cell regions CR and the inter-cell separation region FR. In some example embodiments, the mask pattern may have a stack structure including an oxide layer pattern and a Si nitride layer pattern. The plurality of fin-type active regions F1 may extend in parallel to each other and extend lengthwise in the first horizontal direction (the X direction). A stack structure including the plurality of sacrificial semiconductor layers 103 and the plurality of nanosheet semiconductor layers NS may remain on the fin upper surface FT of each of the plurality of fin-type active regions F1.

The device isolation layer 112 filling in the trench region TI between each of the plurality of fin-type active regions F1 may be formed. After the device isolation layer 112 is formed, the plurality of sacrificial semiconductor layers 103 and the plurality of nanosheet semiconductor layers NS may protrude above the upper surface of the device isolation layer 112. The device isolation layer 112 may include a silicon oxide layer, but is not limited thereto. To form the device isolation layer 112, a plasma enhanced chemical vapor deposition (PECVD) process, a high density plasma CVD (HDP CVD) process, an inductively coupled plasma CVD (ICP CVD) process, a capacitor coupled plasma CVD (CCP CVD) process, a flowable chemical vapor deposition (FCVD) process, or a spin coating process may be used.

Referring to FIGS. 5A, 5B, and 5C, the plurality of dummy gate structures DGS may be formed in the plurality of cell regions CR and the inter-cell separation region FR in the results of FIGS. 4A and 4B.

As illustrated in FIG. 5C, the plurality of dummy gate structures DGS arranged in the plurality of cell regions CR among the plurality of dummy gate structures DGS may cover upper surfaces and side walls of the plurality of sacrificial semiconductor layers 103 and the plurality of nanosheet semiconductor layers NS and extend lengthwise in the second horizontal direction (the Y direction).

As illustrated in FIG. 5C, among the plurality of dummy gate structures DGS, the plurality of dummy gate structures DGS arranged in the inter-cell separation region FR may include a plurality of linear portions DL extending lengthwise in the second horizontal direction (the Y direction) and a plurality of bridge portions DB1 and DB2 (hereinafter, also referred to as the first bridge portion DB1 and the second bridge portion DB2) integrally connected to each of the two linear portions DL adjacent to each other in the first horizontal direction (the X direction) among the plurality of linear portions DL and extending in a direction crossing the first horizontal direction (the X direction) from the two linear portions DL. In some example embodiments, the width of each of the plurality of second bridge portions DB2 may be greater than the width of each of the plurality of linear portions DL.

As illustrated in FIG. 5C, the plurality of bridge portions DB1 and DB2 in the plurality of dummy gate structures DGS arranged in the inter-cell separation region FR may extend lengthwise in a direction crossing the second horizontal direction (the Y direction), for example, the first horizontal direction (the X direction). However, the inventive concepts are not limited thereto. In some example embodiments, the plurality of bridge portions DB1 and DB2 may have a variety of shapes, such as a curved portion, a bent portion, etc. when viewed from a plane (e.g., a X-Y plane).

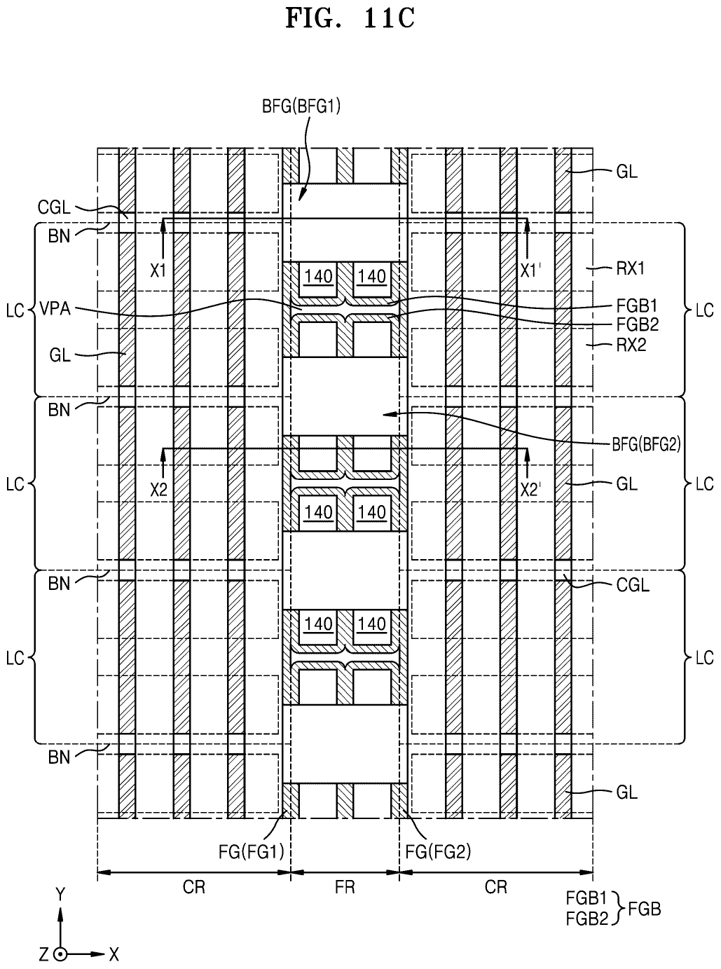

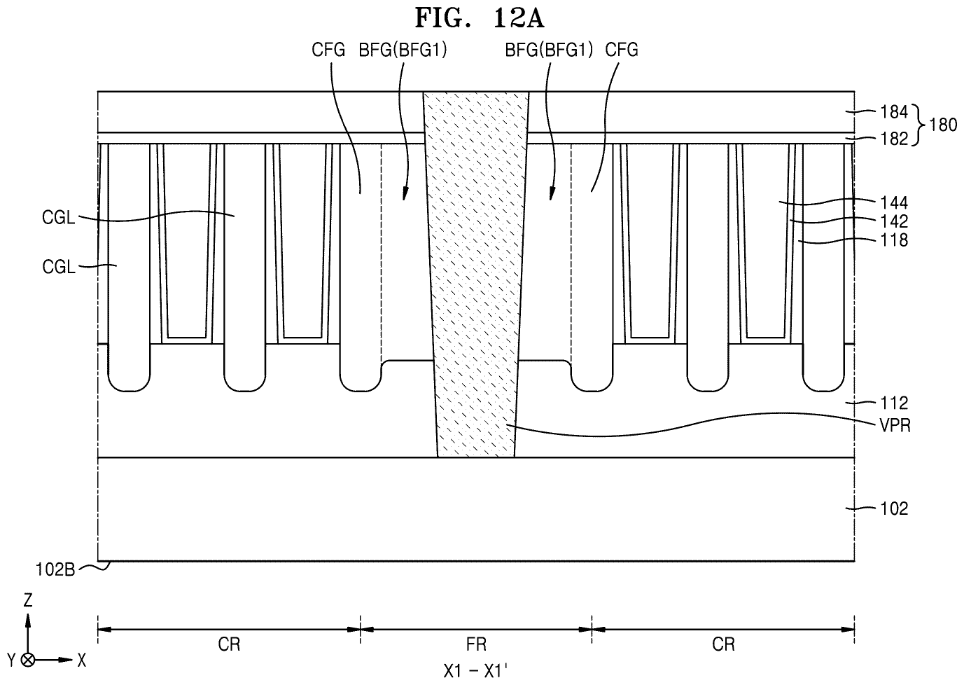

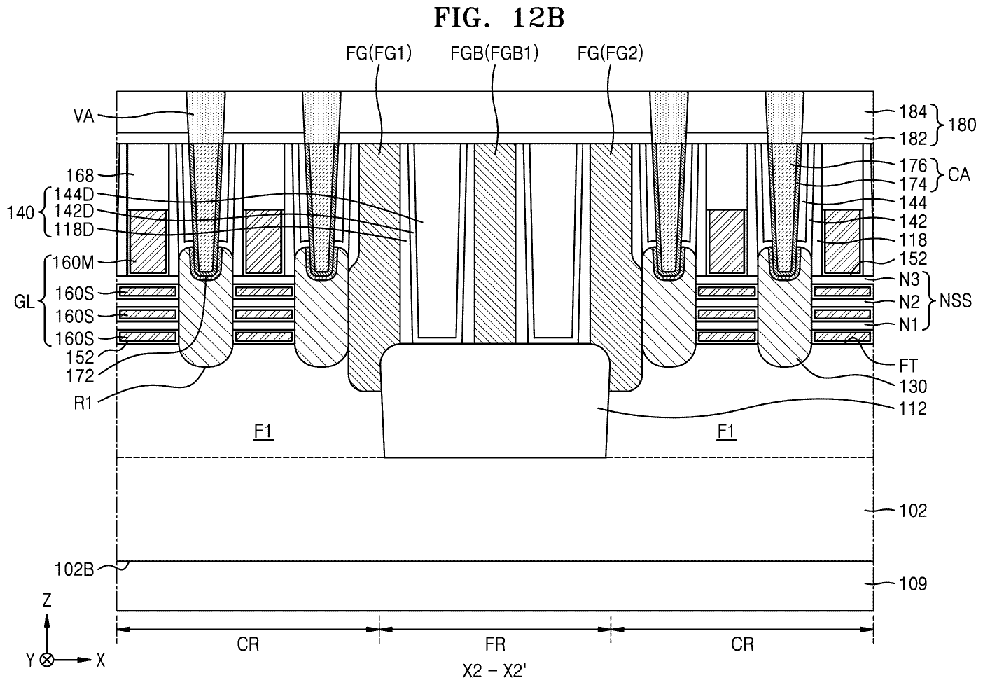

In each of the plurality of cell regions CR and the inter-cell separation regions FR, the plurality of dummy gate structures DGS may each have a structure in which an oxide layer D122, a dummy gate layer D124, and a capping layer D126 are sequentially stacked. In some example embodiments, the oxide layer D122 may be obtained by oxidizing a surface of each of the plurality of sacrificial semiconductor layers 103 and the plurality of nanosheet semiconductor layers NS (see FIG. 12). In this case, as illustrated in FIGS. 5A and 5B, the upper surface of the device isolation layer 112 may not be covered with the oxide layer D122. In some example embodiments, the oxide layer D122 may be formed by a deposition process. In this case, unlike the illustration of FIGS. 5A and 5B, the oxide layer D122 may cover the upper surface of the device isolation layer 112. The dummy gate layer D124 may include polysilicon and the capping layer D126 may include a silicon nitride layer.

The nanosheet stack NSS may be arranged below each of the plurality of dummy gate structures DGS arranged in the plurality of cell regions CR among the plurality of dummy gate structures DGS, as illustrated in FIG. 5B. Therefore, the plurality of dummy gate structures DGS may each be physically supported by the nanosheet stack NSS, and thus, structural defects, such as being bent or tilted in an undesired direction due to stress from the surrounding environment during a subsequent process, may be prevented or reduced.

Among the plurality of dummy gate structures DGS, the plurality of dummy gate structures DGS3 arranged in the inter-cell separation region FR do not include the nanosheet stack NSS thereunder. However, as illustrated in FIG. 5C, the plurality of dummy gate structures DGS3 arranged in the inter-cell separation region FR may include the plurality of linear portions DL and the bridge portions DB connected to the plurality of linear portions DL. Therefore, the plurality of linear portions DL included in the plurality of dummy gate structures DGS may be supported by the plurality of bridge portions DB, and thus, structural defects, such as being bent or tilted in an unwanted direction due to stress from the surrounding environment during a subsequent process, may be prevented or reduced. Therefore, the dummy gate structure DGS in the plurality of cell regions CR may be prevented or reduced from being adversely affected by the structural defect such as bending or tilting of the plurality of dummy gate structures DGS. Accordingly, in the subsequent process, the plurality of gate lines GL obtained from the plurality of dummy gate structures DGS in the plurality of cell regions CR may be precisely arranged in a desired position. Therefore, in the manufacturing process of the integrated circuit device 100, defects such as undesired short-circuit or disconnection of the plurality of gate lines GL and conductive lines adjacent thereto may be prevented or reduced from occurring.

As illustrated in FIGS. 5A and 5B, the plurality of insulating spacers 118 covering both side walls of each of the plurality of dummy gate structures DGS may be formed. Then, by using the plurality of dummy gate structures DGS and the plurality of insulating spacers 118 as etching masks to selectively etch a portion of each of the plurality of sacrificial semiconductor layers 103 and the plurality of nanosheet semiconductor layers NS and a portion of the fin-type active region F1, the plurality of nanosheet semiconductor layers NS (see FIG. 4B) may be divided into the plurality of nanosheet stacks NSS including the first nanosheet N1, the second nanosheet N2, and the third nanosheet N3, and the plurality of recesses R1 may be formed on the plurality of fin-type active regions F1. Dry etching, wet etching, or a combination thereof may be used to form the plurality of nanosheet stacks NSS and the plurality of recesses R1.

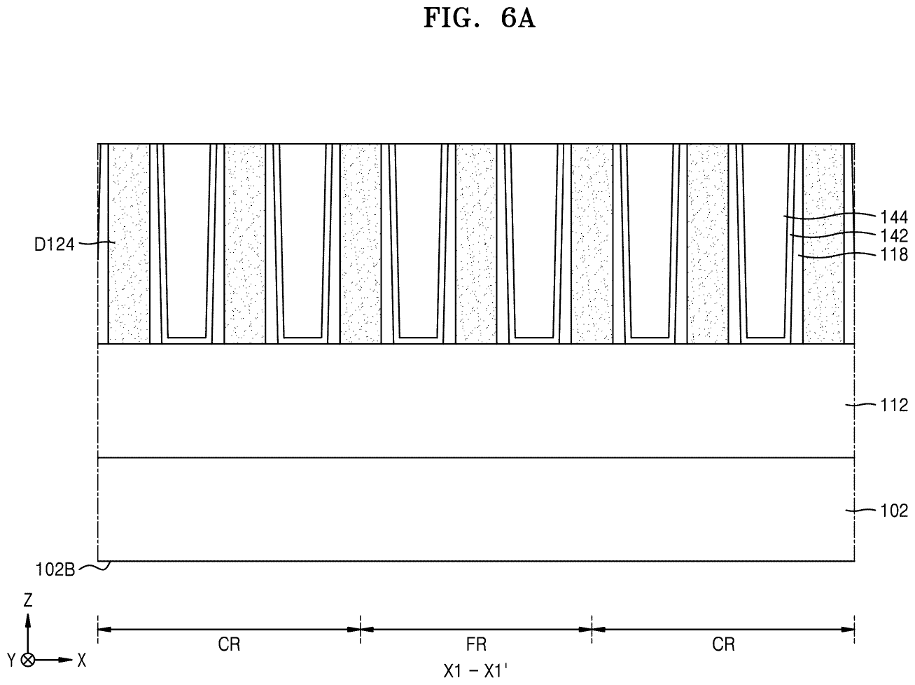

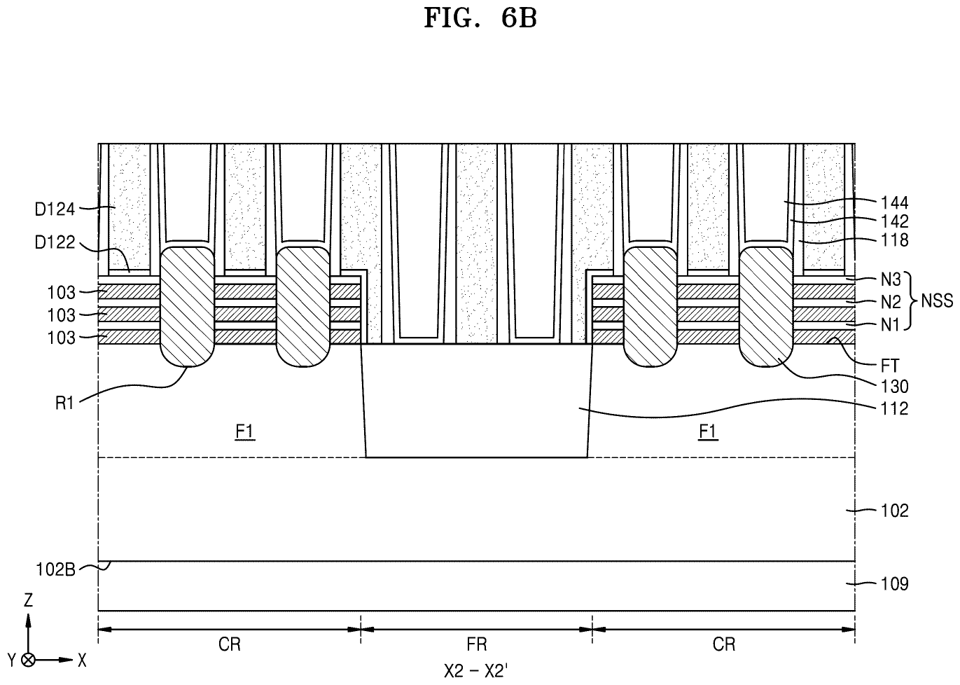

Referring to FIGS. 6A and 6B, the plurality of source/drain regions 130 filling in the plurality of recesses R1 in the results of FIGS. 5A, 5B, and 5C may be formed. To form the plurality of source/drain regions 130, a semiconductor material may be epitaxially grown from the surface of the fin-type active region F1 exposed at the bottom surface of the plurality of recesses R1 and the side walls of each of the first nanosheet N1, the second nanosheet N2, and the third nanosheet N3 included in the nanosheet stack NSS.

Subsequently, after forming an insulating liner 142 covering the result in which the plurality of source/drain regions 130 are formed, an inter-gate insulating layer 144 may be formed on the insulating liner 142, and a portion of the each of the insulating liner 142 and the inter-gate insulating layer 144 may be etched to expose upper surfaces of the plurality of capping layers D126. Subsequently, the plurality of capping layers D126 may be removed to expose the dummy gate layer D124, and the insulating liner 142 and the inter-gate insulating layer 144 may be partially removed such that an upper surface of the inter-gate insulating layer 144 and an upper surface of the dummy gate layer D124 are approximately on the same level.

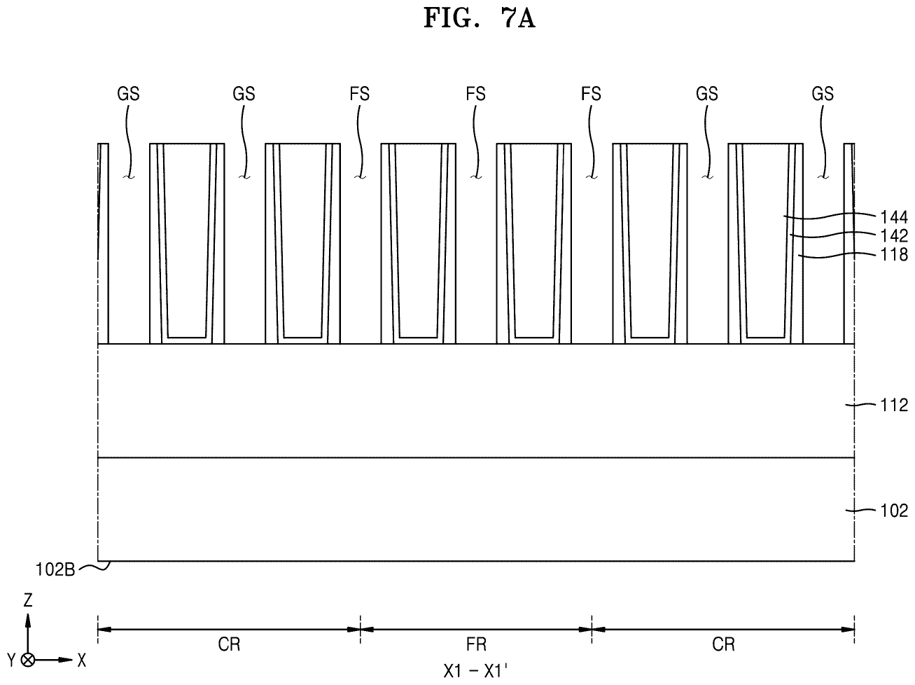

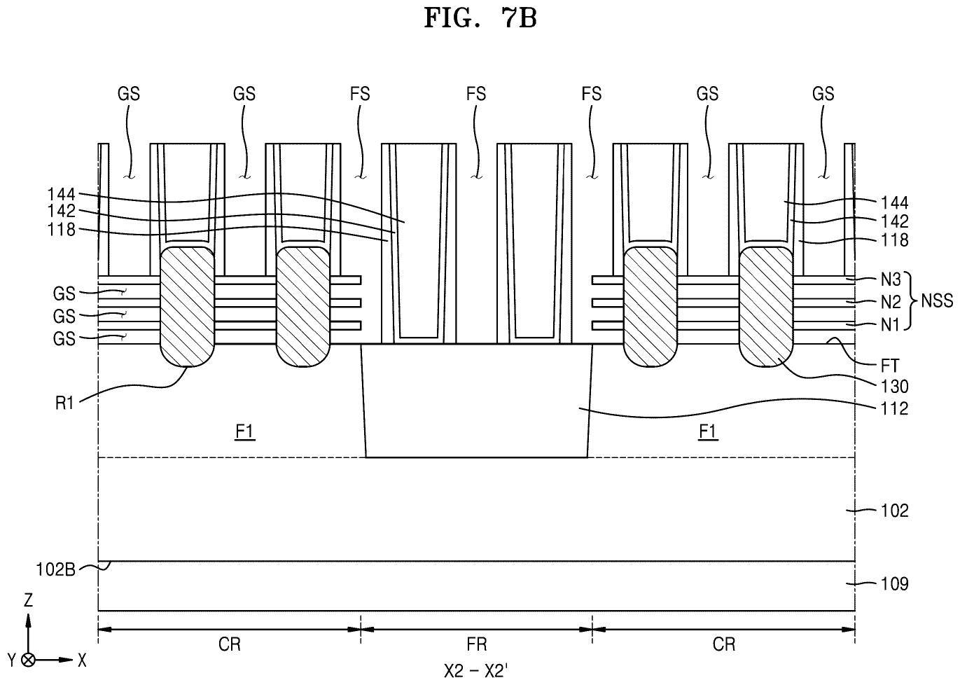

Referring to FIGS. 7A and 7B, in the result of FIGS. 6A and 6B, the dummy gate layer D124 and the oxide layer D122 therebelow may be removed, and then, the plurality of sacrificial semiconductor layers 103 remaining on the fin-type active region F1 may be selectively removed through spaces from which the dummy gate layer D124 and the oxide layer D122 are removed. In some example embodiments, to selectively remove the plurality of sacrificial semiconductor layers 103, the etching selectivity difference between the first nanosheet N1, the second nanosheet N2, and the third nanosheet N3 and the plurality of sacrificial semiconductor layers 103 may be used. Liquid or gas etchant may be used to selectively remove the plurality of sacrificial semiconductor layers 103. In some example embodiments, to selectively remove the plurality of sacrificial semiconductor layers 103, a CH₃COOH-based etchant, for example, an etchant including a mixture of CH₃COOH, HNO₃, and HF, or an etchant including a mixture of CH₃COOH, H₂O₂, and HF may be used, but embodiments are not limited thereto.

After the plurality of sacrificial semiconductor layers 103 are selectively removed, a plurality of gate spaces GS extending lengthwise in the second horizontal direction (the Y direction) may be formed in the plurality of cell regions CR, and the plurality of nanosheet stacks NSS may be exposed through the plurality of gate spaces GS. In the inter-cell separation region FR, a plurality of dummy gate spaces FS extending lengthwise in the second horizontal direction (the Y direction) may be formed, and the upper surface of the device isolation layer 112 may be exposed through the plurality of dummy gate spaces FS. Among the plurality of dummy gate spaces FS, in the dummy gate space FS passing through a boundary between the inter-cell separation region FR and the cell region CR, pieces of the first nanosheet N1, the second nanosheet N2, and the third nanosheet N3 remaining on an end of the fin-type active region F1 adjacent to the inter-cell separation region FR and the device isolation layer 112 may together be exposed.

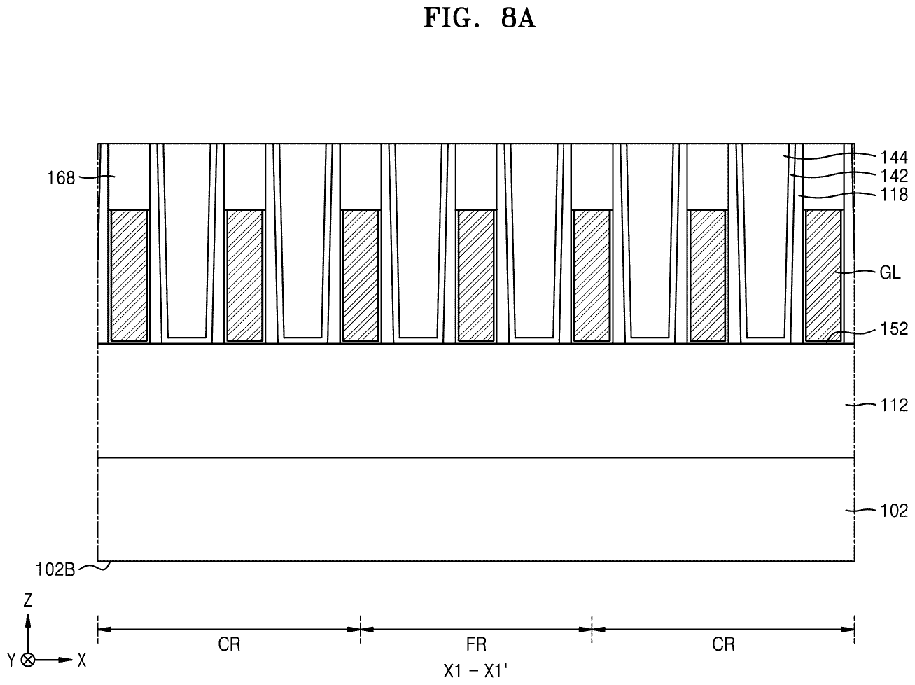

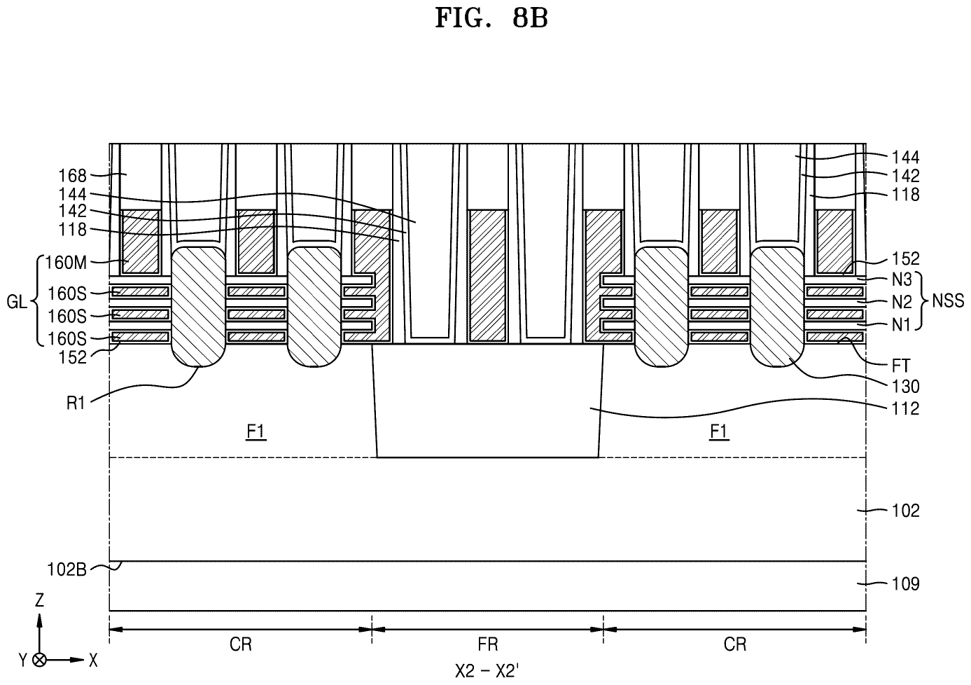

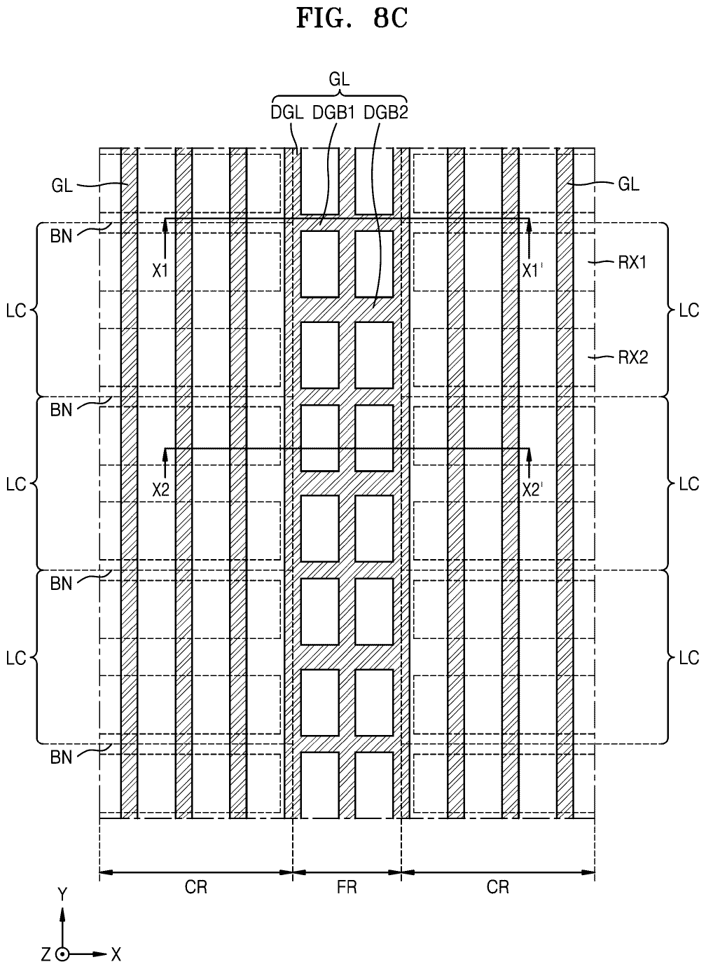

Referring to FIGS. 8A, 8B, and 8C, in the results of FIGS. 7A and 7B, the gate dielectric layer 152 covering surfaces exposed through the plurality of gate spaces GS and the plurality of dummy gate spaces FS may be formed. The gate dielectric layer 152 may cover surfaces of each of the first nanosheet N1, the second nanosheet N2, and the third nanosheet N3, the fin-type active region F1, the device isolation layer 112, and the insulating spacer 118. An atomic layer deposition (ALD) process may be used to form the gate dielectric layer 152.

Subsequently, the gate line GL filling in a portion of each of the plurality of gate spaces GS and the plurality of dummy gate spaces FS on the gate dielectric layer 152, and the capping insulating pattern 168 covering the upper surface of each of the gate line GL and the gate dielectric layer 152 in each of the plurality of gate spaces GS and the plurality of dummy gate spaces FS may be formed.

FIG. 8C illustrates a plane structure of the plurality of gate lines GL formed on the substrate 102. As illustrated in FIG. 8C, among the plurality of gate lines GL, the plurality of gate lines GL arranged in the plurality of cell regions CR may extend lengthwise in the second horizontal direction (the Y direction) on the plurality of fin-type active regions F1.

Among the plurality of gate lines GL, the plurality of gate lines GL arranged in the inter-cell separation region FR may include a plurality of linear gate portions DGL extending lengthwise in the second horizontal direction (the Y direction) and a plurality of bridge gate portions DGB integrally connected to each of the two linear gate portions DGL adjacent to each other in the first horizontal direction (the X direction) among the plurality of linear gate portions DGL and extending in a different direction crossing the first horizontal direction (the X direction) from the two linear gate portions DGL. The plurality of bridge gate portions DGB may include a first bridge gate portion DGB1 overlapping the cell boundary BN in the first horizontal direction (the X direction) and a second bridge gate portion DGB2 overlapping a region between the first device region RX1 and the second device region RX2. A width of the second bridge gate portion DGB2 may be greater than a width of the linear gate portion DL. For example, the width of the second bridge gate portion DGB2 may be 1.5 times or more than the width of the first bridge gate portion DGB1 or the width of the linear gate portion DL.

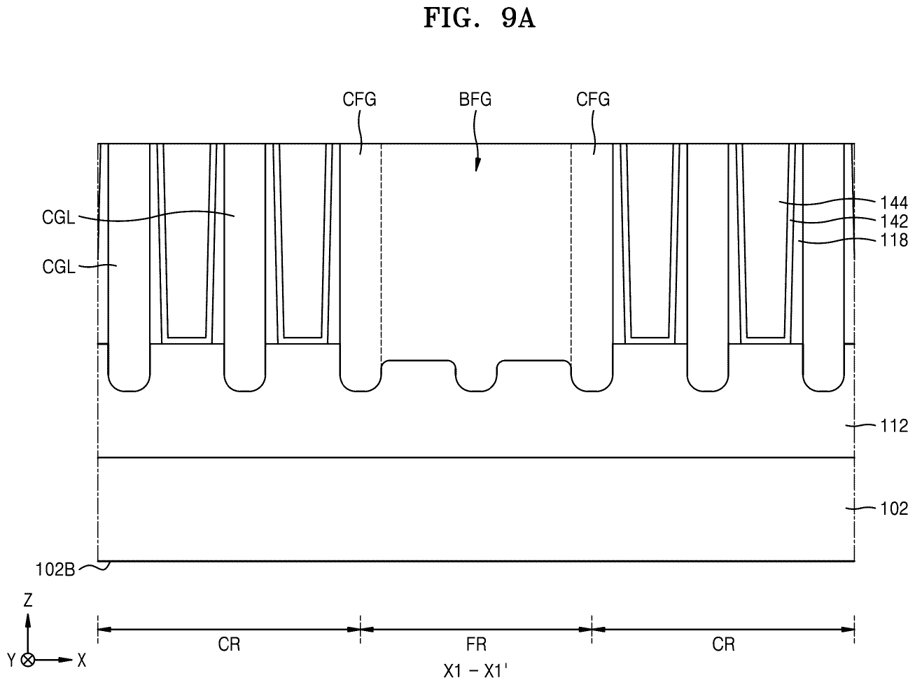

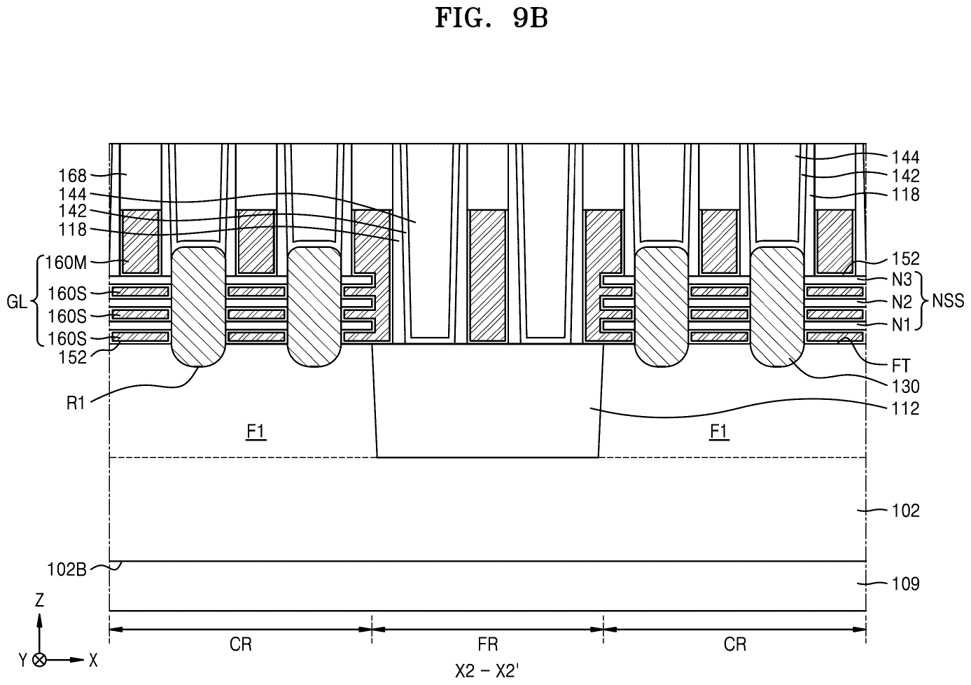

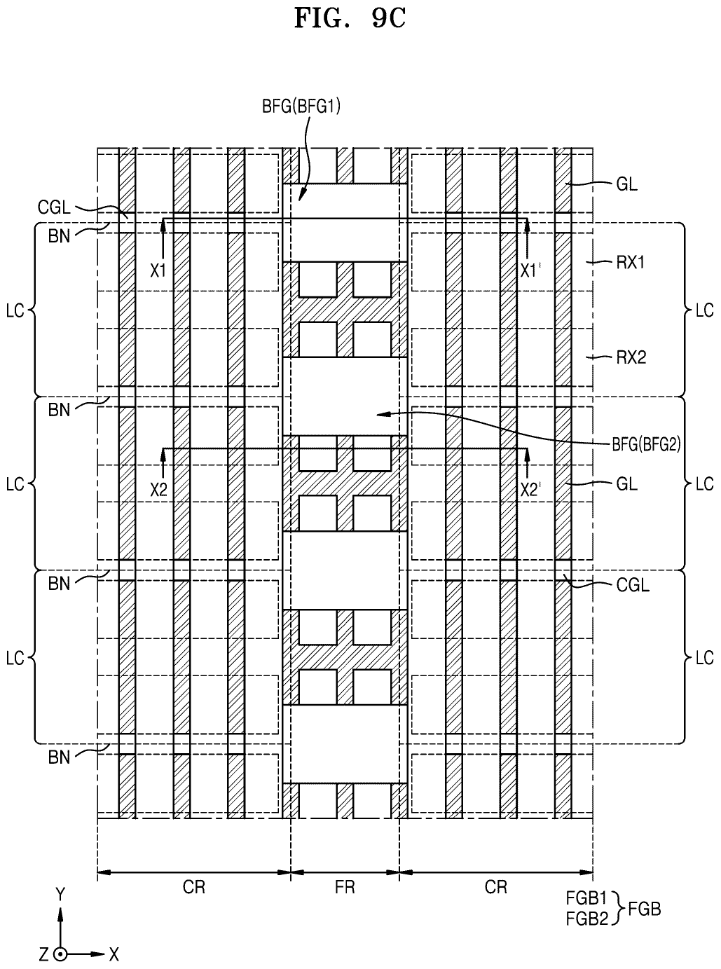

Referring to FIGS. 9A, 9B, and FIG. 9C, in the result of FIGS. 8A, 8B, and 8C, the plurality of gate cut insulating patterns CGL and the plurality of bridge insulating patterns BFG may be formed by substituting, in cut regions selected along the cell boundary BN arranged along the first horizontal direction (the X direction) and an extension of the cell boundary BN in each of a pair of cells CL adjacent in the second horizontal direction (the Y direction), the gate line GL, the gate dielectric layer 152, and the capping insulating pattern 168 with an insulating material.

For example, to form a plurality of gate cut insulating patterns CGL and a plurality of bridge insulating patterns BFG, in the result of FIGS. 8A, 8B, and 8C, a gate cut mask pattern (not shown) including a plurality of cut openings exposing the cut regions on the substrate 102 may be formed, and, by using the gate cut mask pattern as an etching mask, portions of the plurality of capping insulating patterns 168, the plurality of gate lines GL, and the plurality of gate dielectric layers 152 in the result of FIGS. 8A, 8B, and 8C that correspond to the cut regions may be removed to form a plurality of cut spaces. Subsequently, the gate cut mask pattern may be removed, the isolation insulating layer may be formed to fill in the plurality of cut spaces, and the isolation insulating layer may be planarized to expose the upper surface of the plurality of capping insulating patterns 168 remaining on the substrate 102 such that the plurality of gate cut insulating patterns CGL and the plurality of bridge insulating patterns BFG may remain on the substrate 102. The isolation insulating layer may include a silicon nitride layer, but is not limited thereto.

In this case, a length in the second horizontal direction (the Y direction) of at least some of the plurality of bridge insulating patterns BFG may be greater than a length in the second horizontal direction (the Y direction) of the plurality of gate cut insulating patterns CGL. To this end, when forming a plurality of cut openings in the gate cut mask pattern, a width of the plurality of cut openings in the second horizontal direction (the Y direction) in the inter-cell separation region FR may be greater than a width in the second horizontal direction (the Y direction) of the plurality of cut openings in the cell region CR. In this way, as a width of the plurality of cut openings formed in the gate cut mask pattern, in the second horizontal direction (the Y direction), is greater in the inter-cell separation region FR than in the plurality cell regions CR, when performing etching processes to remove portions corresponding to the cut regions among the plurality of capping insulating patterns 168, the plurality of gate lines GL, and the plurality of gate dielectric layers 152, at least a portion of each of the insulating spacer 118, the insulating liner 142, and the inter-gate insulating layer 144 that are adjacent to the layers to be etched and that are exposed through the cut regions may together be removed by an etching atmosphere of the etching processes. As described above, after the isolation insulating layer is formed to fill the plurality of cut spaces and planarized such that the upper surface of the plurality of capping insulating patterns 168 remaining on the substrate 102 is exposed, the plurality of bridge insulating patterns BFG remaining in the inter-cell separation region FR may include only the isolation insulating layer or a combination of the isolation insulating layer and other layers. For example, the plurality of bridge insulating patterns BFG may include a combination of portions of the insulating spacer 118, the insulating liner 142, and the inter-gate insulating layer 144 exposed through the cut regions and remain without being removed, and the isolation insulating layer.

In FIG. 9C, the planar shape of the bridge insulating pattern BFG is illustrated as being a rectangular or roughly rectangular, but the inventive concepts are not limited thereto. For example, the bridge insulating pattern BFG may have various planar shapes such as a circular, elliptical, rhombus shape, an irregular polygon, etc. according to the planar shape of the plurality of cut openings formed in the gate cut mask pattern in the inter-cell separation region FR or a shape of a result obtained by performing an etching process of portions exposed through the cut regions.

As illustrated in FIGS. 9A and 9C, the plurality of bridge insulating patterns BFG may each include a bridge insulating edge portion CFG arranged on an extension of the cell boundary BN along the second horizontal direction (the Y direction) of the cell LC.

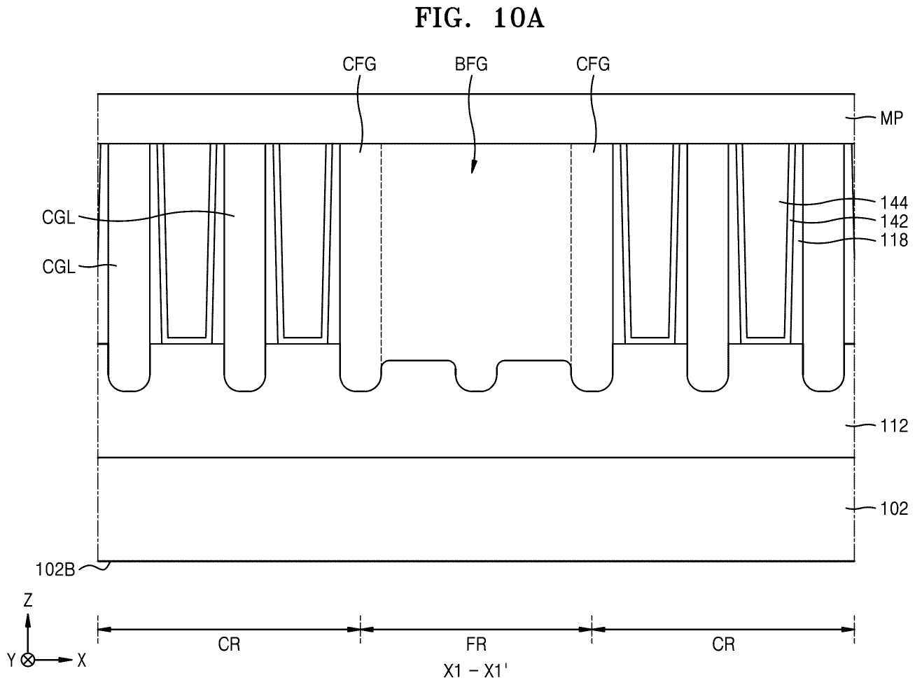

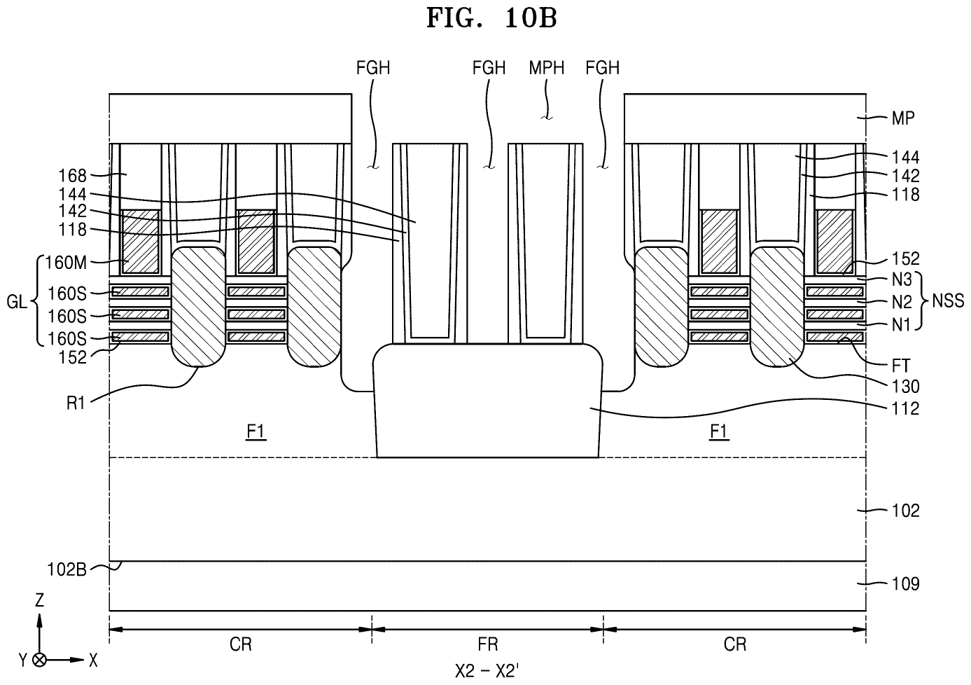

Referring to FIGS. 10A and 10B, in the results of FIGS. 9A, 9B, and 9C, a mask pattern MP including an opening MPH exposing a region of the inter-cell separation region FR excluding portions wherein the plurality of bridge insulating patterns BFG are formed and a portion including the cell boundary BN of each of the plurality of cells LC adjacent to the inter-cell separation region FR may be formed. Subsequently, using the mask pattern MP as an etching mask, in a portion including the inter-cell separation region FR and the cell boundary BN (see FIG. 1) of each of the plurality of cells LC adjacent to the inter-cell separation region FR, the plurality of capping insulating patterns 168, the plurality of gate lines GL, and the plurality of gate dielectric layers 152 may be removed through the opening MPH to form a plurality of dummy insulating spaces FGH.

In some example embodiments, to form the plurality of dummy insulating spaces FGH, through the etching atmosphere during the etching process for removing the plurality of capping insulating patterns 168, the plurality of gate lines GL, and the plurality of gate dielectric layers 152 and through, among the plurality of dummy insulating spaces FGH, the dummy insulating space FGH passing through a boundary between the inter-cell separation region FR and the cell region CR, pieces of the first nanosheet N1, the second nanosheet N2, and the third nanosheet N3 remaining on an end of the fin-type active region F1 adjacent to the inter-cell separation region FR and a portion of the fin-type active region F1 may together be removed.

Through the plurality of dummy insulating spaces FGH, a portion of each of the plurality of fin-type active regions F1 and a portion of the device isolation layer 112 may be exposed. The vertical level of the surface of the plurality of fin-type active regions F1 exposed through the bottom surface of the plurality of dummy insulating spaces FGH may be closer to the substrate 102 than the surface of the device isolation layer 112 exposed through the bottom surface of the plurality of dummy insulating spaces FGH are to the substrate 102.

In some example embodiments, unlike the illustration of FIG. 10A, the mask pattern MP may be formed such that the plurality of bridge insulating patterns BFG are exposed through the opening MPH of the mask pattern MP. In this regard, even if the plurality of bridge insulating patterns BFG are exposed through the opening MPH, the etching process for forming the plurality of dummy insulating spaces FGH may be performed under an etching atmosphere wherein the etching selectivity is controlled such that the plurality of capping insulating patterns 168, the plurality of gate lines GL, and the plurality of gate dielectric layers 152 are selectively removed with respect to the plurality of bridge insulating patterns BFG, the insulating spacer 118, the insulating liner 142, and the inter-gate insulating layer 144 that are exposed through the opening MPH.

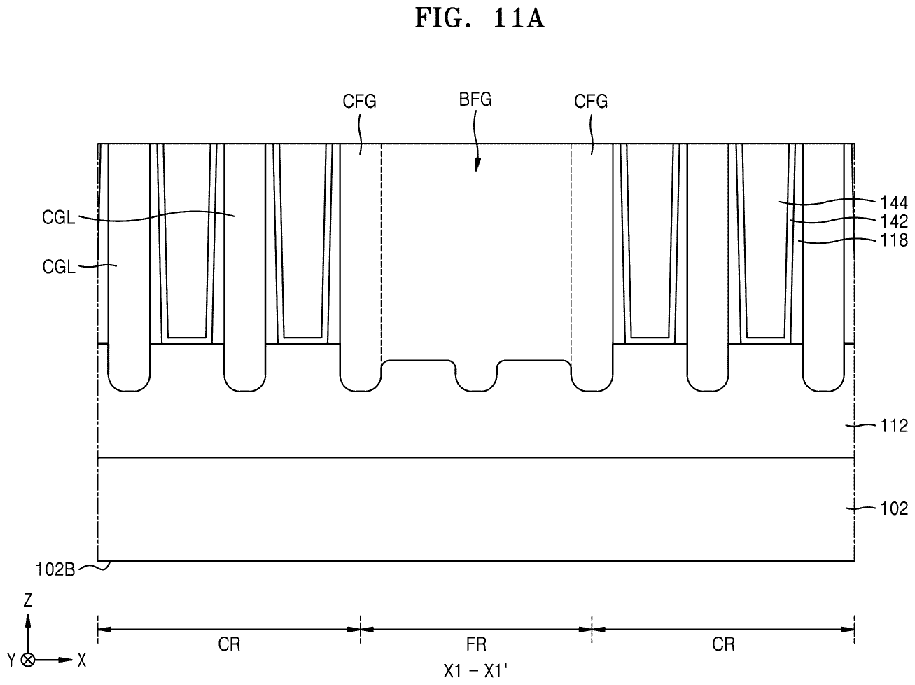

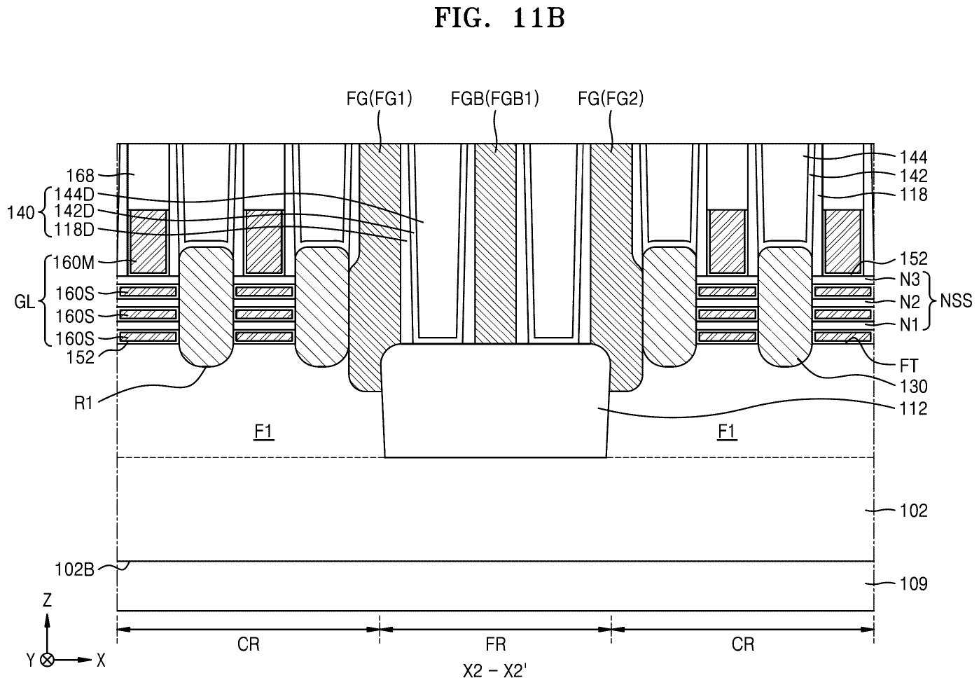

Referring to FIGS. 11A, 11B, and FIG. 11C, the plurality of dummy gate insulating lines FG and the plurality of dummy gate insulating bridge FGB may be formed by removing the mask pattern MP from a result of FIGS. 10A and F10B and filling in a portion of the plurality of dummy insulating spaces FGH.

In some example embodiments, the plurality of dummy gate insulating lines FG and the plurality of dummy gate insulating bridges FGB may include a silicon nitride layer, but are not limited thereto. The plurality of dummy gate insulating lines FG and the plurality of dummy gate insulating bridges FGB may be formed by an atomic layer deposition (ALD) process. For example, silicon nitride may be deposited in the plurality of dummy insulating spaces FGH by the ALD process. Silicon nitride may be deposited on the plurality of dummy insulating spaces FGB, starting from the edges of the plurality of dummy insulating spaces FGB including materials. Since the width of a region corresponding to the second bridge gate portion DGB2 among the plurality of dummy insulating space FGB is greater than a width of a region corresponding to the linear gate portion DL, silicon nitride may fully fill in the region corresponding to the linear gate portion DL. On the other hand, since the region corresponding to the second bridge gate portion DGB2 among the plurality of dummy insulating spaces FGB is not fully filled, the dummy gate insulating bridge FGB including the vacuum space VPA may be formed in the region corresponding to the second bridge gate portion DGB2. That is, in the process of forming the dummy gate insulating bridge FGB, the first dummy gate insulating bridge FGB1 and the second dummy gate insulating bridge FGB2 apart from each other with the vacuum space VPA therebetween may be formed. The width of a region of the dummy gate insulating line FG exposed in the vacuum space VPA may be less than the width of a region of the dummy gate insulating line FG not exposed in the vacuum space VPA.

After the plurality of dummy gate insulating lines FG are formed, in the inter-cell separation region FR, the insulating spacer 118, the insulating liner 142, and the inter-gate insulating layer 144 remaining between each of the plurality of dummy gate insulating lines FG may form the inter-dummy gate insulating structure 140.

Referring to FIGS. 12A and 12B, in the results of FIGS. 11A, 11B, and 11C, after forming the source/drain contact hole penetrating through the insulating liner 142 and the inter-gate insulating layer 144 in the vertical direction (the Z direction) in the plurality of cell regions CR to expose the source/drain region 130, a portion of the source/drain region 130 may be removed through the source/drain contact hole through an anesthetic etching process such that the source/drain contact hole extends more toward the substrate 102. Subsequently, the metal silicide layer 172 may be formed on the source/drain region 130 exposed in the bottom surface of the source/drain contact hole. In some example embodiments, to form the metal silicide layer 172, a metal liner (not shown) conformally covering the exposed surface of the source/drain region 130 may be formed and heat-treated to induce a reaction between the source/drain region 130 and a metal included in the metal liner. After the metal silicide layer 172 is formed, the remaining portion of the metal liner may be removed. During the process of forming the metal silicide layer 172, a portion of the source/drain region 130 may be removed. In some example embodiments, when the metal silicide layer 172 includes a titanium silicide layer, the metal liner may include a Ti layer. Subsequently, the source/drain contact CA including the conductive barrier layer 174 and the contact plug 176 may be formed on the metal silicide layer 172.

Subsequently, the etch stop layer 182 and the upper insulating layer 184 may be sequentially formed on exposed surfaces on the substrate 102 in the plurality of cell regions CR and the inter-cell separation region FR to form the upper insulating structure 180.

Subsequently, the plurality of source/drain via contacts VA penetrating through the upper insulating structure 180 in the vertical direction (the Z direction) in the plurality of cell regions CR and connected to the plurality of source/drain contacts CA, and the gate contact CB penetrating through the upper insulating structure 180 and the capping insulating pattern 168 in the vertical direction (the Z direction) and connected to the gate line GL (see FIG. 3C) may be formed. In addition, the plurality of via power rails VPR penetrating through the upper insulating structure 180, the plurality of bridge insulating patterns BFG, and the device isolation layer 112 in the vertical direction in the inter-cell separation region FR may be formed. The order of forming the source/drain via contact VA, the gate contact CB, and via power rail VPR is not particularly limited.

Subsequently, the interlayer insulating layer 192 covering the upper insulating structure 180 and the via power rail VPR, and the plurality of upper wiring layers M1 penetrating through the interlayer insulating layer 192 and each connected to the source/drain via contact VA, the gate contact CB, and the via power rail VPR may be formed.

Subsequently, as illustrated in FIGS. 3A, 3B, and 3C, the vertical thickness (the thickness in the Z direction) of the substrate 102 may be reduced by removing a portion of the substrate 102 from the backside surface 102B of the substrate 102. To reduce the vertical thickness (the thickness in the Z direction) of the substrate 102, at least one process selected from a mechanical grinding process, a chemical mechanical polishing (CMP) process, a wet etching process, or a combination thereof may be used. As a result, the exposed backside surface 102B of the substrate 102 may become closer to the device isolation layer 112.

Subsequently, as illustrated in FIG. 3A, the insulating spacer IL penetrating through the substrate 102 in the vertical direction (the Z direction), and the backside power rail MW penetrating through the substrate 102 in the vertical direction (the Z direction) and being in contact with an end of the via power rail VPR may be formed. Subsequently, as illustrated in FIGS. 3A, 3B, and FIG. 3C, the integrated circuit device 100 may be manufactured by forming the backside surface 102B of the substrate 102 and the backside insulating layer 109 covering the backside power rail MW and forming the power line PL penetrating through the backside insulating layer 109 in the vertical direction (the Z direction) and being in contact with an end of the backside power rail MW.

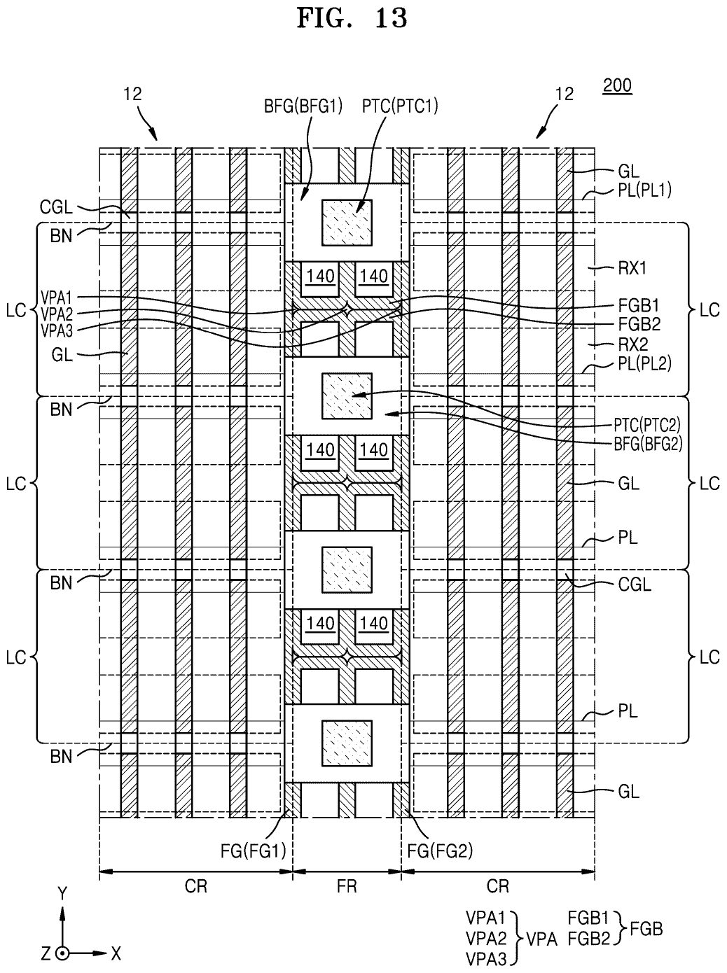

FIG. 13 is a layout diagram of a portion of an integrated circuit device according to some example embodiments. Comparing FIGS. 1 and 13, a portion of the first dummy gate insulating bridge FGB1 and a portion of the second dummy gate insulating bridge FGB2 may be in contact with each other. A first horizontal component of the first dummy gate insulating bridge FGB1 and a first horizontal component of the second dummy gate insulating bridge FGB2 may be in contact with each other. In addition, a plurality of vacuum spaces VPA1, VPA2, and VPA3 spaced apart from each other may be arranged in the dummy gate insulating bridge FGB.

Whether or not the second dummy gate insulating bridge FGB1 and the second dummy gate insulating bridge FGB2 are in contact with each other may be determined by a ratio between the linear gate portion DL and the second bridge portion DB2 in FIG. 3. For example, when a ratio of the second bridge portion DB2 relative to the linear gate portion DL is greater than 1 and 2 or less, a portion of the first dummy gate insulating bridge FGB1 and a portion of the second dummy gate insulating bridge FGB2 may be in contact with each other. When a ratio of the second bridge portion DB2 relative to the linear gate portion DL is 2.5 or greater, the first dummy gate insulating bridge FGB1 and the second dummy gate insulating bridge FGB2 may not be in contact with each other.

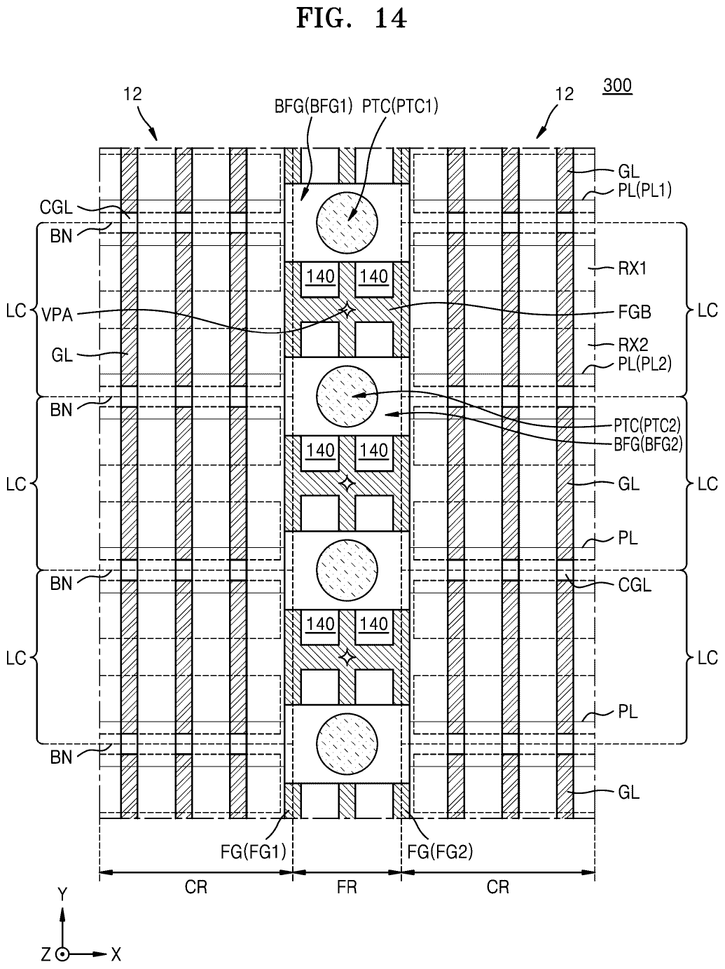

FIG. 14 is a layout diagram of a portion of an integrated circuit device according to some example embodiments. Comparing FIGS. 1 and 14, one vacuum space VPA may be arranged in the central region of the dummy gate insulating bridge FGB. In addition, the first dummy gate insulating line FG1 and the second dummy gate insulating line FG2 may not be exposed in the vacuum space.

As illustrated in FIG. 14, in a planar view including the first horizontal direction (the X direction) and the second horizontal direction (the Y direction), the shape of the cross-section of the power tap cells PTC may be circular. From another view, an interval between regions of the power tap cells PTC overlapping the vacuum space VPA in a second horizontal direction (the Y direction) may be less than an interval between regions of the power tap cells PTC not overlapping the vacuum space VPA. Since the parasitic capacitor between the power tap cells PTC may be reduced and electrical short-circuit may be prevented or reduced in occurrence through the vacuum space VPA, intervals between the power tap cells PTC may be reduced. By increasing the interval between regions of the power tap cells PTC that do not overlap the vacuum space VPA, the parasitic capacitor may be decreased even when there is no vacuum space VPA.

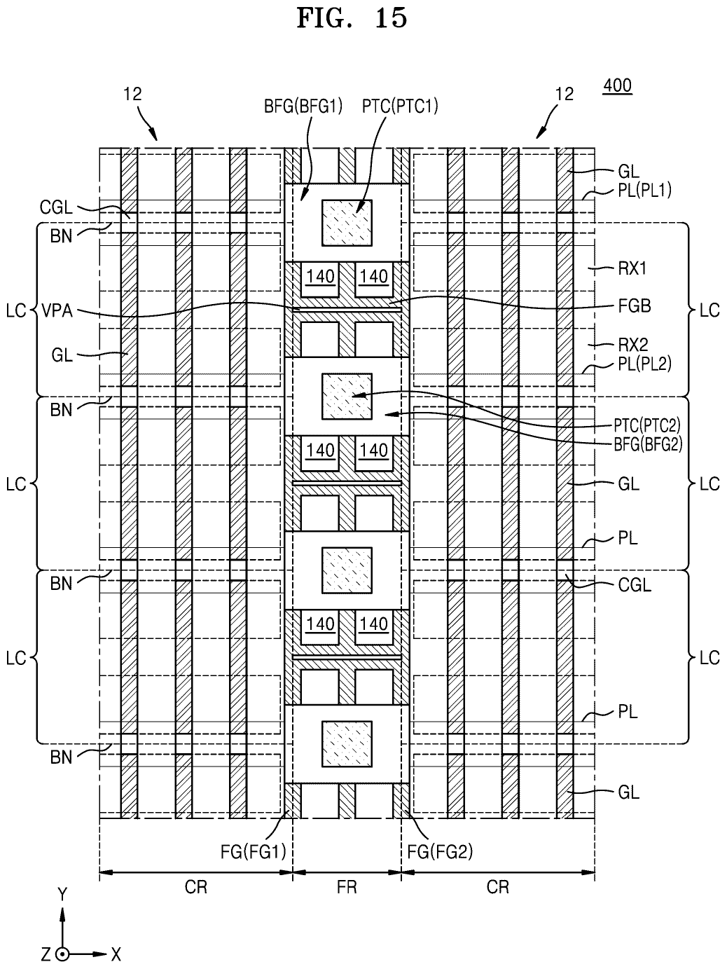

FIG. 15 is a layout diagram of a portion of an integrated circuit device according to some example embodiments. Comparing FIGS. 1 and 15, the vacuum space VPA included in the dummy gate insulating bridge FGB may be constant. The vacuum space VPA shown in FIG. 1 may be formed simultaneously with the dummy gate insulating bridge FGB. In FIG. 15, the vacuum space VPA may further be formed through an etching process after forming the dummy gate insulating bridge FGB.

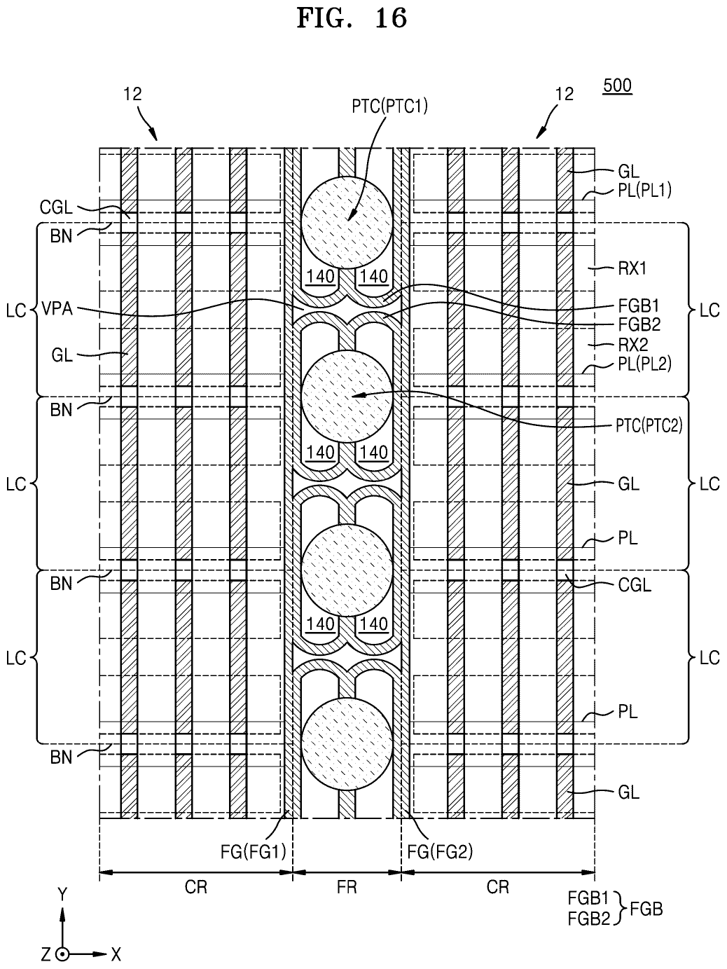

FIG. 16 is a view of an integrated circuit device according to some example embodiments.

Comparing FIGS. 13 and 16, the integrated circuit device of FIG. 16 may not include the bridge insulating pattern BFG. The process of manufacturing the bridge insulating pattern BFG may be omitted in the manufacturing of the integrated circuit device 600. The power tap cells PTC may penetrate through the inter-dummy gate insulating structure 140 and the substrate 102. The power tap cells PTC may be apart from each other in the second horizontal direction (the Y direction) between the first dummy gate insulating line FG1 and the second dummy gate insulating line FG2. It is illustrated that each of the first dummy gate insulating line FG1 and the second dummy gate insulating line FG2 continuously extend in the second horizontal direction (the Y direction), but the inventive concepts are not limited thereto. The first dummy gate insulating line FG1 and the second dummy gate insulating line FG2 may be arranged intermittently by the gate cut insulating pattern CGL. As shown in FIG. 16, the outer peripheral surface of the inter-dummy gate insulating structure 140 be curved. Since the outer peripheral surface of the inter-dummy gate insulating structure 140 is curved, the dummy gate insulating bridge FGB may be greater in size than the vacuum space VPA.

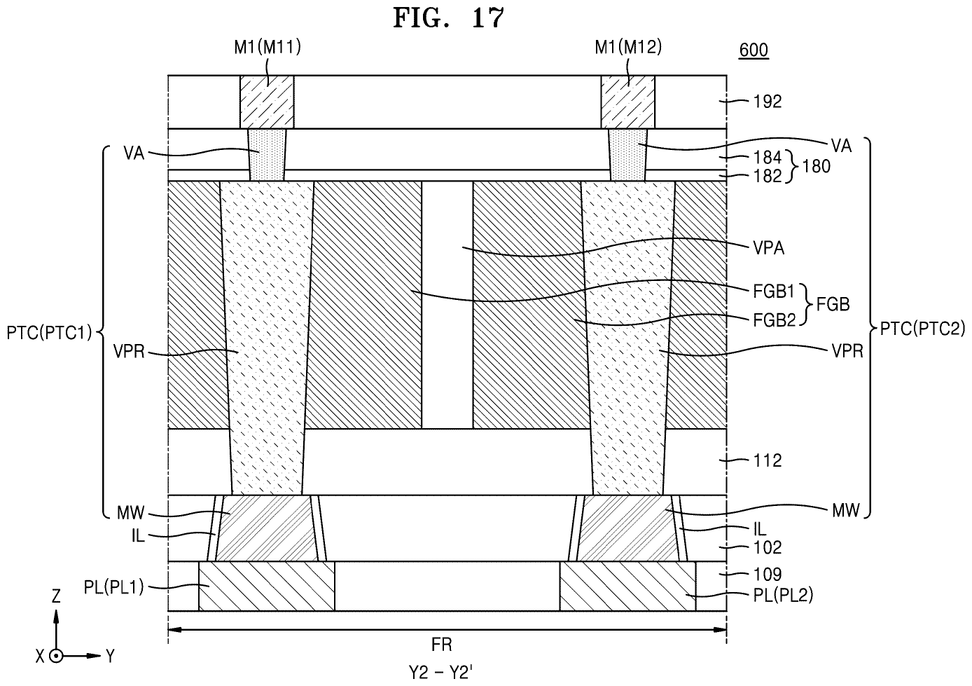

FIG. 17 is a cross-sectional view of an integrated circuit device according to some example embodiments. Comparing FIGS. 3D and 17, the integrated circuit device of FIG. 17 may not include the bridge insulating pattern BFG. The power tap cells PTC may include the backside power rail MW penetrating through the substrate 102, the via power rail VPR penetrating through the inter-dummy gate insulating structure 140, and the via contact VA penetrating through the upper insulating structure 180. Since the backside power rail MW and the via power rail VPR are described above, detailed descriptions thereof will be omitted. The via contact VA may include a metal layer and a conductive barrier layer surrounding the metal layer. The metal layer may include Mo, Co, Cu, W, Ru, Mn, or a combination thereof. The conductive barrier layer 174 may include Ti, Ta, W, TiN, TaN, WN, WCN, TiSiN, TaSIN, WSiN, or a combination thereof, but is not limited thereto. The conductive barrier layer 174 may be omitted in each of the via contacts VA.

The lower end of the via power rail VPR may be in contact with the backside power rail MW, and the upper end of the via power rail VPR may be in contact with the via contact VA. The width of the via power rail VPR may be greater than the width of the backside power rail MW and the width of the via contact VA. Since the width of the backside power rail MW and the width of the via contact VA is small, the parasitic capacitance between the power tap cells PTC may be reduced.

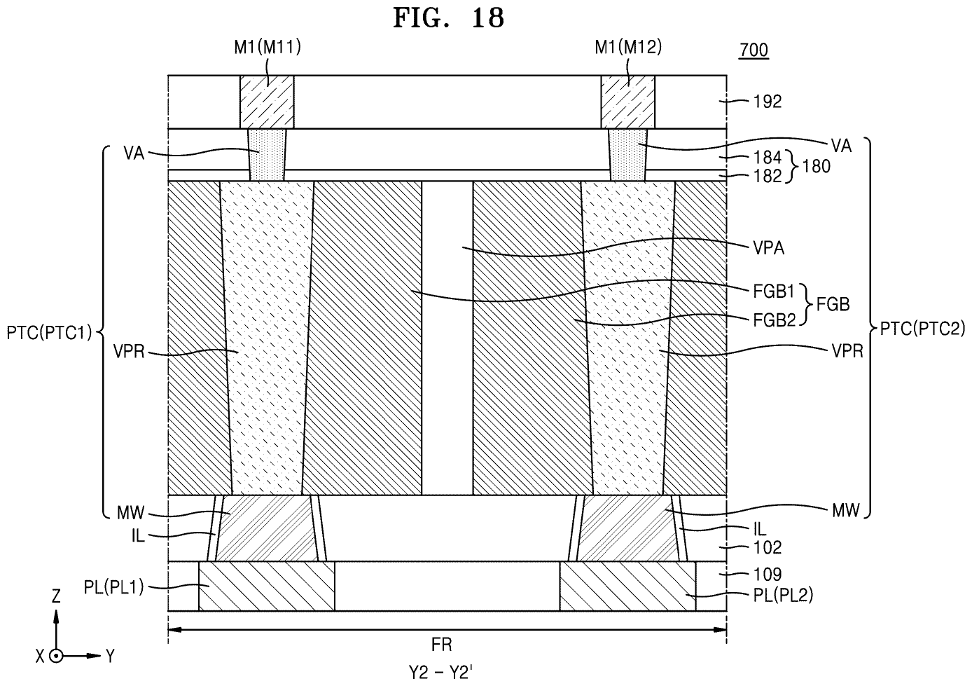

FIG. 18 is a cross-sectional view of an integrated circuit device according to some example embodiments.

Comparing FIGS. 17 and 18, the inter-cell separation region FR may not include the device isolation layer 112. The dummy gate insulating bridge FGB and the vacuum space VPA may be in contact with the substrate 102. From a different view, an interval between the substrate 102 and the vacuum space VPA may be less than an interval between the substrate 102 and the gate line GL included in any one of the plurality of cells. When forming the plurality of dummy gate spaces FS of FIG. 7B, at least a portion of the device isolation layer 112 may be etched. Therefore, the level of the bottom surface of the vacuum space VPA may be lower than the level of the upper surface of the device isolation layer 112. In the drawing, it is illustrated that the device isolation layer 112 is completely removed from the inter-cell separation region FR. However, embodiments are not limited thereto. A portion of the inter-cell separation region FR may be removed.

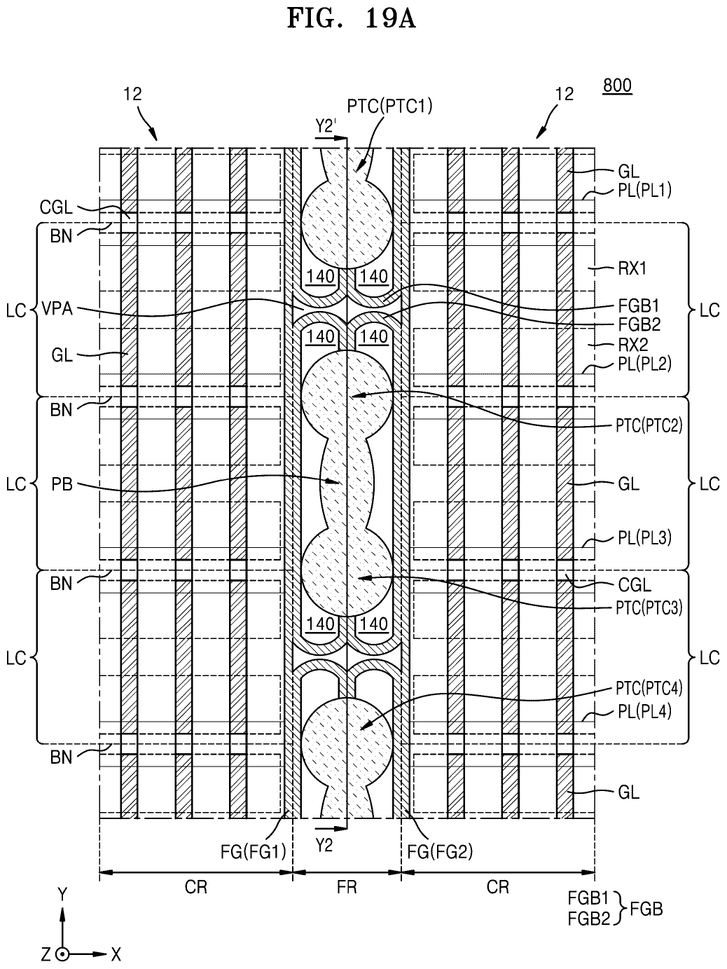

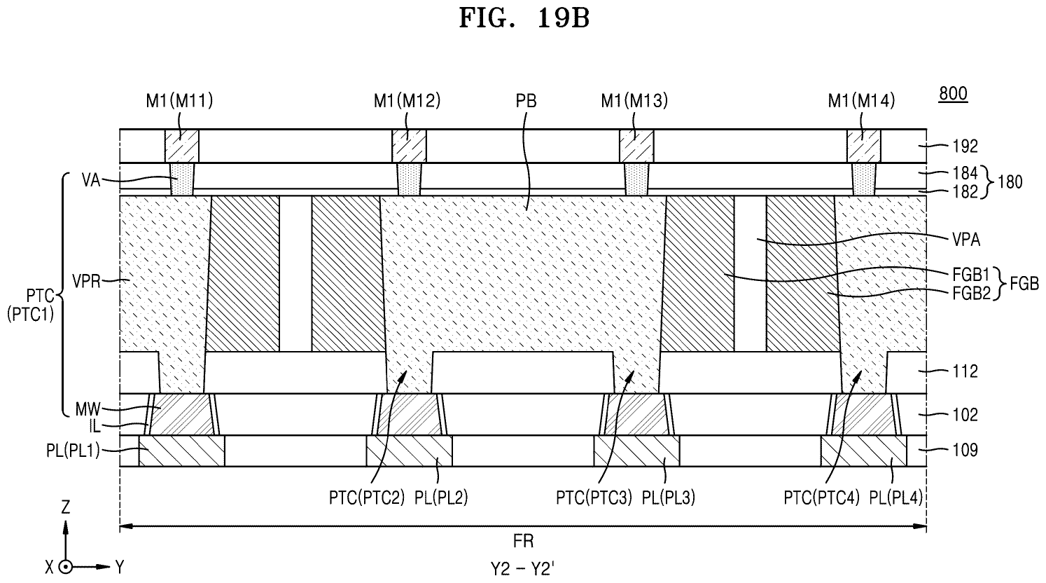

FIGS. 19A and 19B are cross-sectional views of an integrated circuit device according to some example embodiments.

Referring to FIG. 16, the power tap cell PTC and the vacuum space VPA may be alternately arranged in the second horizontal direction (the Y direction) in the inter-cell separation region FR. On the other hand, the plurality of power tap cells PTC are grouped in the inter-cell separation region FR, and the grouped power tap cells PTC and the vacuum space VPA may be alternately arranged in the second horizontal direction (the Y direction). For example, the second power tap cell PTC2 and the third power tap cell PTC may be grouped. The first power tap cell PTC1, the vacuum space VPA, the second power tap cell PTC2, the third power tap cell PTC, the vacuum space VPA, and the fourth power tap cell PTC may be sequentially arranged in the second horizontal direction (the Y direction).

The first voltage may be applied to the first power tap cell PTC1, and the second voltage different from the first voltage may be applied to the second power tap cell PTC2 and a third power tap cell PTC3. A third voltage different from the second voltage may be applied to a fourth power tap cell PTC4. The first voltage and the third voltage may be identical to each other. For example, the ground voltage VSS may be applied to the first power tap cell PTC1 and the fourth power tap cell PTC4, and a power voltage VDD may be applied to the second power tap cell PTC2 and the third power tap cell PTC3.

The vacuum space VPA may be arranged between the power tap cells PTC to which different voltages are applied among adjacent power tap cells PTC so as to reduce the parasitic capacitor between the power tap cells PTC and prevent or reduce the electrical short-circuit between the power tap cells PTC.

A power bridge PB may be further arranged between the power tap cells PTC to which the same voltage is applied. For example, the power bridge PB may be arranged between the second power tap cell PTC2 and the third power tap cell PTC3. One end of the power bridge PB may be in contact with the second power tap cell PTC2, and the other end of the power bridge PB may be in contact with the third power tap cell PTC3. The power bridge PB may be formed together with the via power rail VPR. Since the power bridge PB is connected between the power tap cells PTC to which the same voltage is applied, the power tap cells PTC may be electrically connected in parallel. This may lower the resistance of the power tap cells PTC.

When the terms “about” or “substantially” are used in this specification in connection with a numerical value, it is intended that the associated numerical value includes a manufacturing or operational tolerance (e.g., +10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., +10%) around the stated numerical values or shapes.

While the inventive concept has been particularly shown and described with reference to some example embodiments thereof, it will be understood that various changes in form and details may be made therein without departing from the spirit and scope of the following claims.

What is claimed is:

1. An integrated circuit device comprising:
a first cell region and a second cell region apart from each other in a first horizontal direction on a substrate and each comprising a plurality of cells arranged in a row in a second horizontal direction crossing the first horizontal direction;
an inter-cell separation region extending lengthwise in the second horizontal direction between the first cell region and the second cell region;
a first power line and a second power line overlapping the first cell region, the inter-cell separation region, and the second cell region in a vertical direction to the substrate and being apart from each other in the second horizontal direction;
a first power tap cell penetrating through the substrate in the vertical direction to the substrate and connected to the first power line;
a second power tap cell penetrating through the substrate in the vertical direction to the substrate and connected to the second power line;
a first dummy gate insulating line and a second dummy gate insulating line apart from each other in the first horizontal direction, with the first power tap cell and the second power tap cell therebetween, in the inter-cell separation region, and extending in the second horizontal direction; and
a dummy gate insulating bridge defining a vacuum space and connected to the first dummy gate insulating line and the second dummy gate insulating line.

2. The integrated circuit device of claim 1, wherein
the first power tap cell is configured to receive a first voltage from the first power line, and
the second power tap cell is configured to receive, from the first power line, a second voltage different from the first voltage.

3. The integrated circuit device of claim 1, wherein
the dummy gate insulation bridge defines the vacuum space as a region in which a width is decreased toward at least one of the first horizontal direction and the second horizontal direction away from a center of the vacuum space.

4. The integrated circuit device of claim 1, wherein the vacuum space is defined to have a symmetrical shape with respect to a center of the vacuum space in any one of the first horizontal direction and the second horizontal direction.

5. The integrated circuit device of claim 1, wherein the vacuum space is defined include a first vacuum space and a second vacuum space apart from each other in the dummy gate insulating bridge.

6. The integrated circuit device of claim 1, wherein
the dummy gate insulating bridge comprises a first dummy gate insulating bridge and a second dummy gate insulating bridge defining the vacuum space therebetween and respectively connected to the first bridge insulating pattern and the second bridge insulating pattern.

7. The integrated circuit device of claim 6, wherein at least a portion of the first dummy gate insulating bridge and the second dummy gate insulating bridge are not in contact with each other.

8. The integrated circuit device of claim 6, wherein at least one of the first dummy gate insulating bridge and the second dummy gate insulating bridge has a rounded surface.

9. The integrated circuit device of claim 8, wherein
at least one of the first dummy gate insulating bridge and the second dummy gate insulating bridge comprises a line convex toward the vacuum space in a planar view including the first horizontal direction and the second horizontal direction.

10. The integrated circuit device of claim 1, wherein
an interval between the substrate and the vacuum space is equal to or less than an interval between the substrate and gate lines included in any cell among the plurality of cells.

11. The integrated circuit device of claim 1, wherein
a width of a region of the first dummy gate insulating line and the second dummy gate insulating line, exposed to the vacuum space, is less than a width of a region not exposed to the vacuum space.

12. The integrated circuit device of claim 1, wherein
the first power tap cell is electrically connected to an N-type metal-insulator-semiconductor (NMOS) transistor of the plurality of cells, and
the second power tap cell is electrically connected to a P-type metal-insulator-semiconductor (PMOS) transistor of the plurality of cells.

13. The integrated circuit device of claim 1, further comprising:
a third power line extending in the first horizontal direction and being apart from the second power line;
a third power tap cell penetrating through the substrate in the vertical direction to the substrate and connected to the third power line; and
a power bridge extending in the second horizontal direction and connecting the second power tap cell to the third power tap cell.

14. An integrated circuit device comprising:
a first cell region, an inter-cell separation region, and a second cell region sequentially arranged on a substrate in a first horizontal direction;
a first power line and a second power line overlapping the first cell region, the inter-cell separation region, and the second cell region in a vertical direction to the substrate and being apart from each other in a second horizontal direction crossing the first horizontal direction;
a first power tap cell penetrating through the substrate in the vertical direction and connected to the first power line;
a second power tap cell penetrating through the substrate in the vertical direction and connected to the second power line;
a first dummy gate insulating line and a second dummy gate insulating line apart from each other in the first horizontal direction, with the first power tap cell and the second power tap cell therebetween, in the inter-cell separation region, and each extending in the second horizontal direction; and
a dummy gate insulating bridge defining a vacuum space and connected to the first dummy gate insulating line and the second dummy gate insulating line.

15. The integrated circuit device of claim 14, wherein
the dummy gate insulating bridge defines the vacuum space as a region in which a width is decreased toward at least one of the first horizontal direction and the second horizontal direction away from a center of the vacuum space.

16. The integrated circuit device of claim 14, wherein
the dummy gate insulating bridge comprises a first dummy gate insulating bridge and a second dummy gate insulating bridge defining the vacuum space therebetween and respectively connected to the first bridge insulating pattern and the second bridge insulating pattern.

17. The integrated circuit device of claim 16, wherein at least a portion of each of the first dummy gate insulating bridge and the second dummy gate insulating bridge are not in contact with each other.

18. The integrated circuit device of claim 14, wherein
the first cell region and the second cell region including a plurality of cells, each of the plurality of cells comprises a plurality of gate lines extending lengthwise in the second horizontal direction, and
a length of the first dummy gate insulating line and the second dummy gate insulating line is less than a length of at least one gate line among the plurality of gate lines.

19. An integrated circuit device comprising:
a first cell region and a second cell region apart from each other on a substrate in a first horizontal direction and each comprising a plurality of cells;
an inter-cell separation region arranged between the first cell region and the second cell region on the substrate and extending lengthwise in a second horizontal direction crossing the first horizontal direction;
a plurality of gate lines extending lengthwise in the second horizontal direction in each of the plurality of cells;
a first dummy gate insulating line and a second dummy gate insulating line extending lengthwise in the second horizontal direction in the inter-cell separation region and being apart from each other in the first horizontal direction;
a first power line and a second power line overlapping the first cell region, the inter-cell separation region, and the second cell region in a vertical direction to the substrate and being apart from each other in the second horizontal direction;
a first inter-dummy gate insulating structure and a second inter-dummy gate insulating structure arranged between the first dummy gate insulating line and the second dummy gate insulating line and being apart from each other in the second horizontal direction;
a first power tap cell penetrating through the first inter-dummy gate insulating structure and the substrate in the vertical direction to the substrate and connected to the first power line;
a first power tap cell penetrating through the second inter-dummy gate insulating structure and the substrate in the vertical direction to the substrate and connected to the second power line; and
a dummy gate insulating bridge defining a vacuum space and connected to the first inter-dummy gate insulating structure, the second inter-dummy gate insulating structure, the first dummy gate insulating line, and the second dummy gate insulating line.

20. The integrated circuit device of claim 19, wherein the vacuum space overlaps at least one of the plurality of gate lines in the second horizontal direction.
